(19) United States
(12) Patent Application Publication
(10) Pub. No.: US 2026/0231637 A1
(43) Pub. Date: Aug. 6, 2026

(54) DISPLAY APPARATUS AND ELECTRONIC DEVICE INCLUDING THE SAME

(71) Applicant: Samsung Display Co., Ltd., Yongin-Si (KR)

(72) Inventors: Nahyeon Cha, Yongin-si (KR); Junhyun Park, Yongin-si (KR); Hwarang Lee, Yongin-si (KR); Junki Jeong, Yongin-si (KR)

(21) Appl. No.: 19/457,704

(22) Filed: Jan. 23, 2026

(30) Foreign Application Priority Data
Jan. 31, 2025 (KR) 10-2025-0012635

(51) Int. Cl. H10K 59/131; G09G 3/32; G09G 3/3233; G09G 3/3266; G09G 3/3291; H10K 59/121

(52) U.S. Cl. CPC H10K 59/131; G09G 3/32; G09G 3/3233; G09G 3/3266; G09G 3/3291; H10K 59/1213; H10K 59/1216; G09G 2300/0426; G09G 2300/0452; G09G 2300/0819; G09G 2300/0852; G09G 2300/0861; G09G 2310/0213; G09G 2310/08; G09G 2330/021

(57) ABSTRACT

A display apparatus and an electronic device including the same are provided. The display apparatus includes pixel circuits arranged in a first direction and a second direction, first gate lines and second gate lines extending in the first direction, and data lines extending in the second direction. Among the pixel circuits, a pixel circuit arranged in an odd-numbered column and a pixel circuit arranged in an even-numbered column that neighbor each other are electrically connected to one data line, and pixel circuits in odd-numbered columns of an odd-numbered row and pixel circuits in even-numbered columns of an even-numbered row are each electrically connected to corresponding first gate lines among the first gate lines, and pixel circuits in even-numbered columns of the odd-numbered row and pixel circuits in odd-numbered columns of the even-numbered row are each electrically connected to corresponding second gate lines among the second gate lines.

### CROSS-REFERENCE TO RELATED APPLICATION

This application is based on and claims priority to Korean Patent Application No. 10-2025-0012635, filed on Jan. 31, 2025, in the Korean Intellectual Property Office, the disclosure of which is incorporated by reference herein in its entirety.

### BACKGROUND

### Field

One or more embodiments relate to a display apparatus and an electronic device including the same.

### Description of the Related Art

In general, a display apparatus includes a plurality of gate lines, a plurality of data lines, and a plurality of pixels. Each of the plurality of pixels is electrically connected to a corresponding gate line and a corresponding data line. As high-resolution and large-sized display apparatuses have been developed, the number of data lines therein has increased, thereby increasing the manufacturing costs.

### SUMMARY

One or more embodiments include a display apparatus with a reduced number of data lines and an electronic device including the display apparatus. One or more embodiments include a display apparatus further capable of preventing or reducing an increase in power consumption and an electronic device including the display apparatus. However, such a technical feature is an example, and one or more embodiments are not limited thereto.

Additional aspects will be set forth in part in the description which follows and, in part, will be apparent from the description, or may be learned by practice of the presented embodiments of the disclosure.

According to one or more embodiments, a display apparatus includes pixel circuits arranged in a first direction and a second direction crossing the first direction, first gate lines and second gate lines extending in the first direction, and data lines extending in the second direction. A pixel circuit arranged in an odd-numbered column and a pixel circuit arranged in an even-numbered column that neighbor each other in the first direction among the pixel circuits are electrically connected to one data line. Pixel circuits arranged in odd-numbered columns of an odd-numbered row and pixel circuits arranged in even-numbered columns of an even-numbered row among the pixel circuits are each electrically connected to corresponding first gate lines among the first gate lines. Pixel circuits arranged in even-numbered columns of the odd-numbered row and pixel circuits arranged in odd-numbered columns of the even-numbered row among the pixel circuits are each electrically connected to corresponding second gate lines among the second gate lines.

In an embodiment, each of the pixel circuits may include a first transistor electrically connected between a driving voltage line and a light-emitting diode, and a second transistor electrically connected between a corresponding data line among the data lines and the first transistor. The second transistor of one pixel circuit among the pixel circuit arranged in the odd-numbered column and the pixel circuit arranged in the even-numbered column that neighbor each other in the first direction may be connected to a corresponding first gate line among the first gate lines, and the second transistor of another pixel circuit may be connected to a corresponding second gate line among the second gate lines.

In an embodiment, the first transistor may be an oxide semiconductor transistor.

In an embodiment, the second transistor may include a second gate electrode, and in a plan view, the second gate electrode may have an island shape.

In an embodiment, the display apparatus may further include light-emitting diodes electrically connected to the pixel circuits. Light-emitting diodes electrically connected to a same data line among the light-emitting diodes may emit light of a same color.

In an embodiment, the light-emitting diodes may include first light-emitting diodes emitting light of a first color, second light-emitting diodes emitting light of a second color, and third light-emitting diodes emitting light of a third color. In each odd-numbered light-emitting diode column, the first light-emitting diodes and the second light-emitting diodes may alternate with each other in the second direction, and in each even-numbered light-emitting diode column, the third light-emitting diodes may be arranged in the second direction.

In an embodiment, the light-emitting diodes may include first light-emitting diodes emitting light of a first color, second light-emitting diodes emitting light of a second color, and third light-emitting diodes emitting light of a third color. A first light-emitting diode column in which the first light-emitting diodes are arranged in the second direction, a second light-emitting diode column in which the second light-emitting diodes are arranged in the second direction, and a third light-emitting diode column in which the third light-emitting diodes are arranged in the second direction may be sequentially repeated in the first direction.

In an embodiment, the display apparatus may further include light-emitting diodes electrically connected to the pixel circuits. The light-emitting diodes may include first light-emitting diodes emitting light of a first color, second light-emitting diodes emitting light of a second color, and third light-emitting diodes emitting light of a third color. Odd-numbered data lines among the data lines may be electrically connected to the first light-emitting diodes and the third light-emitting diodes, and even-numbered data lines among the data lines may be electrically connected to the second light-emitting diodes.

In an embodiment, a first light-emitting diode column in which the first light-emitting diodes and the third light-emitting diodes alternate with each other in the second direction, a second light-emitting diode column in which the second light-emitting diodes are arranged in the second direction, a third light-emitting diode column in which the third light-emitting diodes and the first light-emitting diodes alternate with each other in the second direction, and a fourth light-emitting diode column in which the second light-emitting diodes are arranged in the second direction may be sequentially repeated in the first direction.

According to one or more embodiments, a display apparatus includes a first pixel circuit and a second pixel circuit neighboring each other in a first pixel circuit row, a third pixel circuit and a fourth pixel circuit neighboring each other in a second pixel circuit row, a data driver configured to output data signals to data lines, a first gate driver configured to sequentially output first gate signals to first gate lines, and a second gate driver configured to sequentially output second gate signals to second gate lines. Each of the first pixel circuit and the fourth pixel circuit is electrically connected to corresponding first gate lines among the first gate lines, and each of the second pixel circuit and the third pixel circuit is electrically connected to corresponding second gate lines among the second gate lines.

In an embodiment, the first pixel circuit, the second pixel circuit, the third pixel circuit, and the fourth pixel circuit may be electrically connected to a first data line among the data lines.

In an embodiment, the first data line may be arranged between the first pixel circuit and the second pixel circuit, and between the third pixel circuit and the fourth pixel circuit.

In an embodiment, a data signal corresponding to the first data line may include a first data voltage corresponding to the first pixel circuit, a second data voltage corresponding to the second pixel circuit, a fourth data voltage corresponding to the fourth pixel circuit, and a third data voltage corresponding to the third pixel circuit. The first data voltage, the second data voltage, the fourth data voltage, and the third data voltage may be sequentially output.

In an embodiment, the display apparatus may further include a first light-emitting diode electrically connected to the first pixel circuit, a second light-emitting diode electrically connected to the second pixel circuit, a third light-emitting diode electrically connected to the third pixel circuit, and a fourth light-emitting diode electrically connected to the fourth pixel circuit. The first, second, third, and fourth light-emitting diodes may emit light of a same color.

In an embodiment, a distance between the first pixel circuit and the first light-emitting diode may be different from a distance between the second pixel circuit and the second light-emitting diode.

In an embodiment, the display apparatus may further include a fifth pixel circuit and a sixth pixel circuit neighboring each other in the first pixel circuit row, a seventh pixel circuit and an eighth pixel circuit neighboring each other in the second pixel circuit row, a fifth light-emitting diode electrically connected to the fifth pixel circuit, a sixth light-emitting diode electrically connected to the sixth pixel circuit, a seventh light-emitting diode electrically connected to the seventh pixel circuit, and an eighth light-emitting diode electrically connected to the eighth pixel circuit. The fifth pixel circuit, the sixth pixel circuit, the seventh pixel circuit, and the eighth pixel circuit may be electrically connected to a second data line among the data lines.

In an embodiment, each of the first, second, third, and fourth light-emitting diodes may emit green light, each of the fifth light-emitting diode and the sixth light-emitting diode may emit blue light, and each of the seventh light-emitting diode and the eighth light-emitting diode may emit red light.

In an embodiment, the second gate driver may be configured to output the second gate signal that is delayed by a certain period from the first gate signal output from the first gate driver.

In an embodiment, each of the first, second, third, and fourth pixel circuits may include a first transistor electrically connected between a driving voltage line and a light-emitting diode, and a second transistor electrically connected between a corresponding data line among the data lines and the first transistor. The second transistor of each of the first pixel circuit and the fourth pixel circuit may be electrically connected to the corresponding first gate lines among the first gate lines, and the second transistor of each of the second pixel circuit and the third pixel circuit may be electrically connected to the corresponding second gate lines among the second gate lines.

In an embodiment, the first transistor may be an oxide semiconductor transistor.

According to one or more embodiments, an electronic device includes a display apparatus, a memory storing an image data signal or an input control signal, and one or more processors configured to transfer the image data signal or the input control signal stored in the memory to the display apparatus. The display apparatus includes a first pixel circuit and a second pixel circuit neighboring each other in a first pixel circuit row, a third pixel circuit and a fourth pixel circuit neighboring each other in a second pixel circuit row, first gate lines and second gate lines extending in a first direction, and data lines extending in a second direction crossing the first direction. The first pixel circuit, the second pixel circuit, the third pixel circuit, and the fourth pixel circuit are electrically connected to a first data line among the data lines. Each of the first pixel circuit and the fourth pixel circuit is electrically connected to corresponding first gate lines among the first gate lines, and each of the second pixel circuit and the third pixel circuit is electrically connected to corresponding second gate lines among the second gate lines.

In an embodiment, each of the first, second, third, and fourth pixel circuits may include a first transistor electrically connected between a driving voltage line and a light-emitting diode, and a second transistor electrically connected between the first data line and the first transistor. The second transistor of each of the first pixel circuit and the fourth pixel circuit may be connected to the corresponding first gate lines among the first gate lines, and the second transistor of each of the second pixel circuit and the third pixel circuit may be connected to the corresponding second gate lines among the second gate lines.

In an embodiment, the display apparatus may further include a first light-emitting diode electrically connected to the first pixel circuit, a second light-emitting diode electrically connected to the second pixel circuit, a third light-emitting diode electrically connected to the third pixel circuit, and a fourth light-emitting diode electrically connected to the fourth pixel circuit. The first, second, third, and fourth light-emitting diodes may emit light of a same color.

In an embodiment, the electronic device may be an electronic device for image display, a wearable electronic device, or an automotive electronic device.

### BRIEF DESCRIPTION OF THE DRAWINGS

The above and other aspects, features, and advantages of certain embodiments of the disclosure will be more apparent from the following description taken in conjunction with the accompanying drawings.

FIGS. 1A and 1B are each a schematic plan view of a display apparatus according to an embodiment.

FIG. 2 is a schematic diagram of an electronic device according to an embodiment.

FIG. 3 is a schematic cross-sectional view of a display apparatus according to an embodiment.

FIG. 4 is an equivalent circuit diagram schematically showing pixels according to an embodiment.

FIG. 5 is a schematic plan view of pixel circuits according to an embodiment.

FIG. 6 is a diagram for schematically describing a connection between pixel circuits and data lines and gate lines, according to an embodiment.

FIGS. 7A and 7B are each a diagram for schematically describing a connection between pixel circuits and light-emitting diodes, according to an embodiment.

FIG. 8 is a diagram for describing gate voltages and data voltages that are applied to the pixel circuits shown in FIG. 6.

FIG. 9 is a schematic plan view of a portion of a display apparatus according to an embodiment.

FIG. 10 is a diagram for schematically describing operations of pixel circuits and light-emitting diodes of the display apparatus of FIG. 9.

FIG. 11 is a schematic diagram of a data voltage that is applied to a first data line of the display apparatus of FIG. 9.

FIG. 12 is a diagram for schematically describing a connection between pixel circuits and data lines and gate lines, according to an embodiment.

FIG. 13 is a diagram for schematically describing a connection between the pixel circuits shown in FIG. 12 and light-emitting diodes.

FIG. 14 is a diagram for describing gate voltages and data voltages that are applied to the pixel circuits shown in FIG. 12.

FIG. 15 is a diagram for schematically describing a connection between pixel circuits and data lines and gate lines, according to an embodiment.

FIG. 16 is a diagram for describing gate voltages and data voltages that are applied to the pixel circuits shown in FIG. 15.

FIG. 17 is a block diagram of an electronic device according to an embodiment.

FIG. 18 schematically shows an electronic device according to various embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term "and/or" includes any and all combinations of one or more of the associated listed items. Throughout the disclosure, the expression "at least one of a, b or c" indicates only a, only b, only c, both a and b, both a and c, both b and c, all of a, b, and c, or variations thereof.

While such terms as "first" and "second" may be used to describe various elements, such elements must not be limited to the above terms. The above terms are used only to distinguish one element from another. As used herein, the terms "even-numbered" and "odd-numbered" are not used in a restrictive sense but are used to distinguish elements that are arranged sequentially.

The singular forms "a," "an," and "the" as used herein are intended to include the plural forms as well unless the context clearly indicates otherwise.

It will be understood that the terms "include," "comprise," and "have" as used herein specify the presence of stated features or elements but do not preclude the addition of one or more other features or elements.

It will be further understood that, when a layer, region, or element is referred to as being on another layer, region, or element, it may be directly or indirectly on the other layer, region, or element. That is, for example, intervening layers, regions, or elements may be present.

It will be further understood that, when layers, regions, or elements are referred to as being connected to each other, they may be directly connected to each other and/or may be indirectly connected to each other with intervening layers, regions, or elements therebetween. For example, when layers, regions, or elements are referred to as being electrically connected to each other, they may be directly electrically connected to each other and/or may be indirectly electrically connected to each other with intervening layers, regions, or elements therebetween.

In the present description, the direction x, the direction y, and the direction z are not limited to directions along three axes of the rectangular coordinate system and may be interpreted in a broader sense. For example, the direction x, the direction y, and the direction z may be perpendicular to one another or may represent different directions that are not perpendicular to one another.

As used herein, the phrase "in a plan view" indicates that a portion of a target object is seen from above (e.g., viewed in a direction that is perpendicular to an upper surface of a substrate), and the phrase "in a cross-sectional view" indicates that a portion of a target object is vertically cut and the cross-section is viewed from the side.

In the present description, when a first element is referred to as "overlapping" a second element, the first element may be above or below the second element and may at least partially overlap the second element in a plan view.

As used herein, the term "ON" used in association with the state of a device may denote an activated state of the device, and the term "OFF" may denote an inactivated state of the device. The term "ON" used in association with a signal received by a device may denote a signal activating the device, and the term "OFF" may denote a signal inactivating the device. A device may be activated by a high-level voltage or a low-level voltage. For example, a P-channel transistor (a P-type transistor) is activated by a low-level voltage, and an N-channel transistor (an N-type transistor) is activated by a high-level voltage. Therefore, it should be understood that "ON" voltages for a P-type transistor and an N-type transistor are opposite (low versus high) voltage levels.

When an embodiment may be implemented differently, a certain process order may be performed differently from the described order. For example, two consecutively described processes may be performed substantially at the same time or performed in an order opposite to the described order.

Sizes of elements in the drawings may be exaggerated or reduced for convenience of explanation. For example, since sizes and thicknesses of elements in the drawings are arbitrarily illustrated for convenience of description, the following embodiments are not limited thereto.

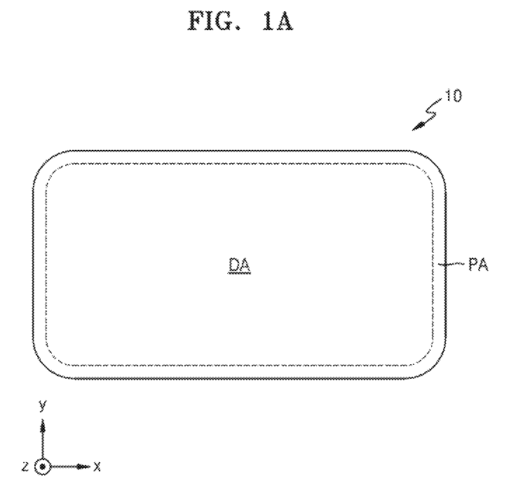

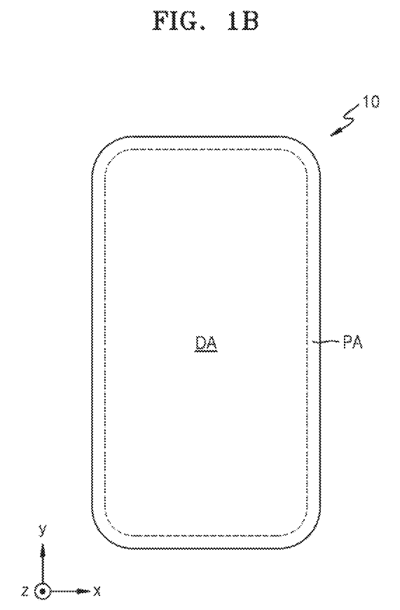

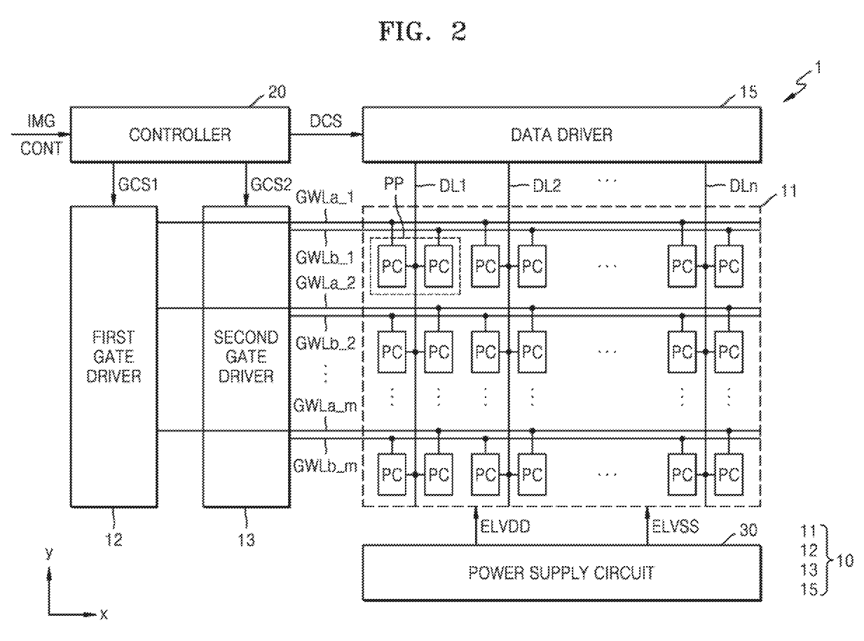

FIGS. 1A and 1B are each a schematic plan view of a display apparatus 10 according to an embodiment. FIG. 2 is a schematic diagram of an electronic device 1 including the display apparatus 10, according to an embodiment.

Referring to FIGS. 1A and 1B, the display apparatus 10 may include a display area DA displaying an image and a peripheral area PA outside the display area DA. The display area DA may be entirely surrounded by the peripheral area PA.

In a plan view, the display area DA may have a rectangular shape. In an embodiment, the display area DA may have another polygonal shape such as a triangle, a pentagon, or a hexagon, or a circular shape, an oval shape, an atypical shape, etc. Corners of edges of the display area DA may have a round shape. In an embodiment, as shown in FIG. 1A, the display apparatus 10 may have the display area DA in which a length in a first direction (a direction x or a row direction) is greater than a length in a second direction (a direction y or a column direction). In an embodiment, as shown in FIG. 1B, the display apparatus 10 may have the display area DA in which a length in the second direction (the direction y) is greater than a length in the first direction (the direction x).

Referring to FIG. 2, the electronic device 1 according to an embodiment may include the display apparatus 10, a controller 20, and a power supply circuit 30. The display apparatus 10 may include a pixel unit 11, a first gate driver 12, a second gate driver 13, and a data driver 15.

The pixel unit 11 may be provided in the display area DA. Various conductive lines configured to transmit electric signals to be applied to the display area DA, outer circuits electrically connected to pixels, and pads on which a printed circuit board or a driver integrated circuit (IC) chip is attached may be positioned in the peripheral area PA. For example, the first gate driver 12 and the second gate driver 13 may be provided in the peripheral area PA.

As shown in FIG. 2, pixel circuits PC connected to first gate lines GWLa_1, GWLa_2, ..., GWLa_m, second gate lines GWLb_1, GWLb_2, ..., GWLb_m, and data lines DL1, DL2, ..., DLn may be arranged in the pixel unit 11. The pixel circuits PC may be arranged in an m×n matrix in a first direction (a direction x) and a second direction (a direction y). In this regard, m and n may each be a natural number of 1 or greater.

Each of the pixel circuits PC may be electrically connected to a corresponding display element (e.g., a light-emitting diode). Display elements may be arranged in various forms, such as a stripe arrangement, a PenTile^{TM} arrangement (a diamond arrangement), and a mosaic arrangement, to display an image. The display elements may be organic light-emitting diodes. Each of the display elements may emit, for example, red, green, blue, or white light. The pixel circuit PC may include a plurality of transistors and at least one capacitor. Each pixel circuit PC may be electrically connected to one corresponding gate line among the first gate lines GWLa_1, GWLa_2, ..., GWLa_m and the second gate lines GWLb_1, GWLb_2, ..., GWLb_m, and may be electrically connected to a corresponding data line among the data lines DL1, DL2, ..., DLn. One pixel may include the pixel circuit PC and an organic light-emitting diode electrically connected to the pixel circuit PC.

The first gate lines GWLa_1, GWLa_2, ..., GWLa_m and the second gate lines GWLb_1, GWLb_2, ..., GWLb_m may each extend in the first direction (the direction x or a row direction) and may be connected to pixel circuits PC that are in the same row. Two pixel circuits PC neighboring each other in the first direction (the direction x) among the pixel circuits PC may be defined as one pixel circuit pair PP. In this regard, when the two pixel circuits PC are referred to as neighboring each other in the first direction (the direction x), the two pixel circuits PC may be adjacent to each other in the first direction (the direction x) without any other pixel circuit arranged between the two pixel circuits PC. One pixel circuit pair PP may be arranged in the same row and may include an odd-numbered pixel circuit and an even-numbered pixel circuit neighboring each other.

Each pixel circuit pair PP may include one pixel circuit connected to a corresponding first gate line among the first gate lines GWLa_1, GWLa_2, ..., GWLa_m and one pixel circuit connected to a corresponding second gate line among the second gate lines GWLb_1, GWLb_2, ..., GWLb_m. For example, pixel circuits PC arranged in odd-numbered columns among pixel circuits PC arranged in a first pixel circuit row may be electrically connected to a first first gate line GWLa_1, and pixel circuits PC arranged in even-numbered columns may be electrically connected to a first second gate line GWLb_1. Pixel circuits PC arranged in odd-numbered columns among pixel circuits PC arranged in a second pixel circuit row may be electrically connected to a second second gate line GWLb_2, and pixel circuits PC arranged in even-numbered columns may be electrically connected to a second first gate line GWLa_2.

In other words, pixel circuits PC arranged in odd-numbered columns of an odd-numbered row and pixel circuits PC arranged in even-numbered columns of an even-numbered row among the pixel circuits PC may each be electrically connected to a corresponding first gate line among the first gate lines GWLa_1, GWLa_2, ..., GWLa_m. Pixel circuits PC arranged in even-numbered columns of the odd-numbered row and pixel circuits PC arranged in odd-numbered columns of the even-numbered row among the pixel circuits PC may each be electrically connected to a corresponding second gate line among the second gate lines GWLb_1, GWLb_2, ..., GWLb_m.

The data lines DL1, DL2, ..., DLn may extend in the second direction (the direction y). The data lines DL1, DL2, ..., DLn may each be arranged between pixel circuits PC arranged in an odd-numbered column and pixel circuits PC arranged in an even-numbered column and may be electrically connected to the pixel circuits PC arranged in the odd-numbered column and the pixel circuits PC arranged in the even-numbered column. That is, the pixel circuits PC belonging to one pixel circuit pair PP may be electrically connected to the same data line.

The first gate driver 12 may be electrically connected to the first gate lines GWLa_1, GWLa_2, ..., GWLa_m, and may be configured to generate a first gate signal in response to a first gate drive control signal GCS1 transmitted from the controller 20 and sequentially supply the same to the first gate lines GWLa_1, GWLa_2, ..., GWLa_m. When the first gate signal is sequentially supplied to the first gate lines GWLa_1, GWLa_2, ..., GWLa_m, pixel circuits PC that are connected to the first gate lines GWLa_1, GWLa_2, ..., GWLa_m may be selected row by row. The data lines DL1, DL2, ..., DLn may be configured to transfer a data voltage to the pixel circuits PC that are connected to a first gate line of each selected row.

The second gate driver 13 may be electrically connected to the second gate lines GWLb_1, GWLb_2, ..., GWLb_m, and may be configured to generate a second gate signal in response to a second gate drive control signal GCS2 transmitted from the controller 20 and sequentially supply the same to the second gate lines GWLb_1, GWLb_2, ..., GWLb_m. When the second gate signal is sequentially supplied to the second gate lines GWLb_1, GWLb_2, ..., GWLb_m, pixel circuits PC that are connected to the second gate lines GWLb_1, GWLb_2, ..., GWLb_m may be selected row by row. The data lines DL1, DL2, ..., DLn may be configured to transfer a data signal to the pixel circuits PC that are connected to a second gate line of each selected row.

In this regard, the first gate lines GWLa_1, GWLa_2, ..., GWLa_m and the second gate lines GWLb_1, GWLb_2, ..., GWLb_m may each be connected to a gate of a data writing transistor included in pixels. The first gate signal and the second gate signal may each be a gate control signal for controlling turn-on and turn-off of the data writing transistor. The first gate signal and the second gate signal may each be a square wave signal in which an on voltage at which the data writing transistor may be turned on and an off voltage at which the data writing transistor may be turned off are repeated.

The data driver 15 may be electrically connected to the data lines DL1, DL2, ..., DLn. The data driver 15 may be configured to convert an image data signal IMG into a data signal in the form of voltage (i.e., a data voltage) according to a data drive control signal DCS input from the controller 20 and output the same. The data lines DL1, DL2, ..., DLn may each be electrically connected to one pixel circuit pair PP with respect to each row, and the data driver 15 may be configured to output a data signal in which a data voltage corresponding to the pixel circuits PC connected to the first gate line and a data voltage corresponding to the pixel circuits PC connected to the second gate line alternate with each other.

The power supply circuit 30 may be configured to supply a first driving voltage ELVDD and a second driving voltage ELVSS to pixels of the pixel unit 11. The first driving voltage ELVDD may be a high-level voltage that is provided to a first electrode (a pixel electrode or an anode) of a display element electrically connected to each pixel circuit PC. The second driving voltage ELVSS may be a low-level voltage that is provided to a second electrode (an opposite electrode or a cathode) of the display element electrically connected to each pixel circuit PC. The first driving voltage ELVDD and the second driving voltage ELVSS may be driving voltages that allow a plurality of pixels to emit light. The power supply circuit 30 may be configured to generate an initialization voltage, a reference voltage, etc., and supply the same to pixels of the pixel unit 11.

The controller 20 may be configured to generate the first gate drive control signal GCS1, the second gate drive control signal GCS2, and the data drive control signal DCS, in response to the image data signal IMG and control signals CONT supplied from an application processor. The controller 20 may be configured to output the first gate drive control signal GCS1 to the first gate driver 12, output the second gate drive control signal GCS2 to the second gate driver 13, and output the data drive control signal DCS to the data driver 15. The controller 20 may be configured to remap image data according to an order in which pixel circuits PC operate. For example, the controller 20 may receive the image data signal IMG from an application processor, decode the received image data signal IMG to convert the same into image data, and store the image data in a graphics memory. The controller 20 may read the image data stored in the graphics memory according to the order in which the pixel circuits PC operate and transfer the same to the data driver 15.

The first gate driver 12 and the second gate driver 13 may be formed directly on a substrate. The data driver 15, the controller 20 and/or the power supply circuit 30 may be arranged on a printed circuit board electrically connected to a pad arranged at one side of the substrate. The printed circuit board may be a flexible printed circuit board (FPCB), which is bendable, a rigid printed circuit board (rigid PCB), which is solid and does not bend easily, or a hybrid printed circuit board including both of a rigid PCB and an FPCB. In an embodiment, the data driver 15, the controller 20 and/or the power supply circuit 30 may be arranged directly on the substrate in a chip-on-glass (COG) or chip-on-plastic (COP) manner. In an embodiment, the data driver 15 and the controller 20 may be integrated into one integrated circuit. For example, the data driver 15 and the controller 20 may be provided as a timing controller embedded driver integrated circuit (a T-con Embedded Driver IC).

Although an organic light-emitting display apparatus including an organic light-emitting diode as a display element is described below as an example of the display apparatus 10 according to an embodiment, the display apparatus 10 described herein is not limited thereto. In an embodiment, the display apparatus 10 described herein may be a display apparatus such as an inorganic light-emitting display (or inorganic electroluminescent (EL) display) or a quantum dot light-emitting display.

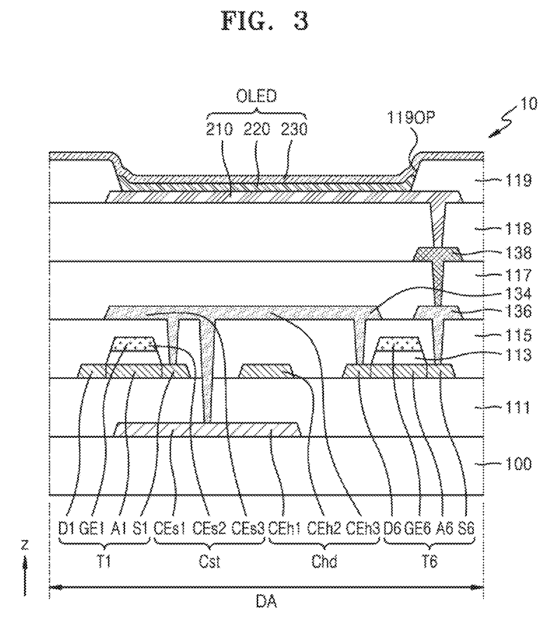

FIG. 3 is a schematic cross-sectional view of the display apparatus 10 according to an embodiment.

Referring to FIG. 3, the display apparatus 10 may include a pixel arranged in the display area DA. One pixel may include a pixel circuit and an organic light-emitting diode OLED electrically connected to the pixel circuit. The pixel circuit may include thin-film transistors and at least one capacitor. A first transistor T1 shown in FIG. 3 may be a driving transistor arranged between a driving voltage line and the organic light-emitting diode OLED, and a sixth transistor T6 may be an emission control transistor arranged between the first transistor T1 and the organic light-emitting diode OLED.

The display apparatus 10 may include a substrate 100. The substrate 100 may include an area corresponding to the display area DA and an area corresponding to the peripheral area PA (refer to FIG. 1A). In the present description, when the substrate 100 is referred to as including the display area DA and the peripheral area PA, the substrate 100 may include an area corresponding to the display area DA and an area corresponding to the peripheral area PA.

The substrate 100 may include a glass material, a ceramic material, a metal material, or a flexible or bendable material. The substrate 100 may include a flexible or bendable material. When the substrate 100 is flexible or bendable, the substrate 100 may include polymer resin, such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may have a single-layer structure or a multi-layer structure. In an embodiment, the substrate 100 may have a multi-layer structure in which an inorganic layer is disposed between base layers including polymer resin.

A first electrode CEs1 of a storage capacitor Cst and a first electrode CEh1 of a hold capacitor Chd may be arranged on the substrate 100. In an embodiment, the first electrode CEs1 of the storage capacitor Cst and the first electrode CEh1 of the hold capacitor Chd may be integrally formed with each other. The first electrode CEs1 of the storage capacitor Cst and the first electrode CEh1 of the hold capacitor Chd may include molybdenum (Mo), aluminum (Al), copper (Cu), titanium (Ti), etc., and may have a single-layer or multi-layer structure.

A buffer layer 111 may be arranged over the first electrode CEs1 of the storage capacitor Cst and the first electrode CEh1 of the hold capacitor Chd. The buffer layer 111 may include an inorganic material, such as oxide or nitride, an organic material, or an organic-inorganic compound, and may have a single-layer or multi-layer structure including an inorganic material and/or an organic material.

A first semiconductor layer A1 of the first transistor T1, a sixth semiconductor layer A6 of the sixth transistor T6, and a second electrode CEh2 of the hold capacitor Chd may be arranged on the buffer layer 111. In an embodiment, the first semiconductor layer A1 of the first transistor T1, the sixth semiconductor layer A6 of the sixth transistor T6, and the second electrode CEh2 of the hold capacitor Chd may include an oxide semiconductor material. For example, the oxide semiconductor material may include oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may be IGZO (In-Ga-Zn-O), ITZO (In-Sn-Zn-O), or IGTZO (In-Ga-Sn-Zn-O).

Each of the first semiconductor layer A1 and the sixth semiconductor layer A6 may include a channel region, and a source region and a drain region arranged at both sides of the channel region. A source region S1 and a drain region D1 of the first semiconductor layer A1, a source region S6 and a drain region D6 of the sixth semiconductor layer A6, and the second electrode CEh2 of the hold capacitor Chd may be doped with impurities.

A gate insulating layer 113 may be arranged on the first semiconductor layer A1 and the sixth semiconductor layer A6. The gate insulating layer 113 may include an inorganic insulating layer, such as silicon oxide, silicon nitride, silicon oxynitride, or aluminum oxide. In an embodiment, the gate insulating layer 113 may be patterned to have a shape corresponding to that of a conductive layer positioned on the gate insulating layer 113.

A first gate electrode GE1 of the first transistor T1 and a sixth gate electrode GE6 of the sixth transistor T6 may be arranged on the gate insulating layer 113. Each of the first gate electrode GE1 of the first transistor T1 and the sixth gate electrode GE6 of the sixth transistor T6 may include molybdenum (Mo), aluminum (Al), copper (Cu), titanium (Ti), etc., and may have a single-layer or multi-layer structure.

In a plan view, the first gate electrode GE1 of the first transistor T1 may overlap the channel region of the first semiconductor layer A1. The first gate electrode GE1 of the first transistor T1 may be integrally formed with a second electrode CEs2 of the storage capacitor Cst. In a plan view, the sixth gate electrode GE6 of the sixth transistor T6 may overlap the channel region of the sixth semiconductor layer A6.

A first insulating layer 115 may be arranged over the first gate electrode GE1 of the first transistor T1, the sixth gate electrode GE6 of the sixth transistor T6, and the second electrode CEh2 of the hold capacitor Chd. The first insulating layer 115 may include an inorganic material, such as oxide or nitride, an organic material, or an organic-inorganic compound, and may have a single-layer or multi-layer structure including an inorganic material and/or an organic material.

A first connection electrode 134 and a second connection electrode 136 may be arranged on the first insulating layer 115. The first connection electrode 134 may electrically connect the source region S1 of the first transistor T1 and the drain region D6 of the sixth transistor T6 to each other through contact holes penetrating the first insulating layer 115. The first connection electrode 134 may be electrically connected to the first electrode CEs1 of the storage capacitor Cst and the first electrode CEh1 of the hold capacitor Chd through contact holes penetrating the buffer layer 111 and the first insulating layer 115. The second connection electrode 136 may be electrically connected to the source region S6 of the sixth transistor T6 through a contact hole penetrating the first insulating layer 115.

The first connection electrode 134 may be integrally formed with a third electrode CEs3 of the storage capacitor Cst and a third electrode CEh3 of the hold capacitor Chd. The first electrode CEs1, the second electrode CEs2, and the third electrode CEs3 of the storage capacitor Cst may overlap one another in a plan view. The first electrode CEh1, the second electrode CEh2, and the third electrode CEh3 of the hold capacitor Chd may overlap one another in a plan view.

The first connection electrode 134 and the second connection electrode 136 may include a conductive material including molybdenum (Mo), aluminum (Al), copper (Cu), titanium (Ti), etc., and may have a multi-layer or single-layer structure including the above-described material. For example, the first connection electrode 134 and the second connection electrode 136 may have a multi-layer structure of titanium (Ti)/aluminum (Al)/titanium (Ti).

A second insulating layer 117 may be arranged over the first connection electrode 134 and the second connection electrode 136. In an embodiment, the second insulating layer 117 may include an organic insulating material such as polymethylmethacrylate (PMMA), polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

A third connection electrode 138 may be arranged on the second insulating layer 117. The third connection electrode 138 may be electrically connected to the second connection electrode 136 through a contact hole penetrating the second insulating layer 117. The third connection electrode 138 may include a conductive material including molybdenum (Mo), aluminum (Al), copper (Cu), titanium (Ti), etc., and may have a multi-layer or single-layer structure including the above-described material. For example, the third connection electrode 138 may have a multi-layer structure of titanium (Ti)/aluminum (Al)/titanium (Ti).

A third insulating layer 118 may be arranged over the third connection electrode 138. The third insulating layer 118 may include an organic material. For example, the third insulating layer 118 may include an organic insulating material such as polymethylmethacrylate (PMMA), polystyrene (PS), a polymer derivative having a phenol-based group, an acryl-based polymer, an imide-based polymer, an aryl ether-based polymer, an amide-based polymer, a fluorine-based polymer, a p-xylene-based polymer, a vinyl alcohol-based polymer, and a blend thereof.

The organic light-emitting diode OLED may be arranged on the third insulating layer 118. The organic light-emitting diode OLED may include a pixel electrode 210, an intermediate layer 220, and an opposite electrode 230.

The pixel electrode 210 may be arranged on the third insulating layer 118. The pixel electrode 210 may be electrically connected to the third connection electrode 138 through a contact hole penetrating the third insulating layer 118. The pixel electrode 210 may be electrically connected to the source region S6 of the sixth transistor T6 through the second connection electrode 136 and the third connection electrode 138.

The pixel electrode 210 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or a compound thereof. In an embodiment, the pixel electrode 210 may further include a conductive oxide layer on and/or under the above-described reflection layer. The conducive oxide layer may include indium tin oxide, indium zinc oxide, zinc oxide, indium oxide, indium gallium oxide and/or aluminum zinc oxide. In an embodiment, the pixel electrode 210 may have a three-layer structure of ITO/Ag/ITO.

A bank layer 119 may be arranged on the pixel electrode 210. An opening 119OP exposing at least a portion of the pixel electrode 210 may be defined in the bank layer 119. A central portion of the pixel electrode 210 may be exposed through the opening 119OP defined in the bank layer 119. The bank layer 119 may prevent an arc or the like from occurring at the edge of the pixel electrode 210 by increasing a distance between the edge of the pixel electrode 210 and the opposite electrode 230. The opening 119OP in the bank layer 119 may define an emission area of the pixel including the organic light-emitting diode OLED.

The bank layer 119 may include an organic insulating material, such as polyimide, polyamide, acrylic resin, benzocyclobutene, hexamethyldisiloxane (HMDSO), and phenolic resin. The bank layer 119 may be formed by a method such as spin coating.

In an embodiment, the bank layer 119 may include a light-blocking material and may be in black. The light-blocking material may include carbon black, carbon nanotubes, resin or paste including black dye, metal particles, for example, nickel (Ni), aluminum (Al), molybdenum (Mo), and alloys thereof, metal oxide (e.g., chromium oxide) particles, or metal nitride (e.g., chromium nitride) particles. When the bank layer 119 includes a light-blocking material, reflection by metal components arranged under the bank layer 119 may be reduced.

The intermediate layer 220 may include an emission layer. The emission layer may include an organic material including a fluorescent or phosphorescent material that emits red, green, blue, or white light. The emission layer may include a low-molecular weight organic material or a polymer organic material, and functional layers, such as a hole transport layer, a hole injection layer, an electron transport layer, and an electron injection layer, may be optionally further arranged on and/or under the emission layer.

The emission layer may have a patterned shape corresponding to the pixel electrode 210. A functional layer such as a hole transport layer may be a single layer over a plurality of pixel electrodes 210.

The opposite electrode 230 may be arranged on the intermediate layer 220. The opposite electrode 230 may include a conductive material having a low work function. For example, the opposite electrode 230 may include a transparent layer or a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the opposite electrode 230 may further include a layer, such as ITO, IZO, ZnO, or In₂O₃, on a transparent layer or a (semi)transparent layer including the above-described material. In an embodiment, the opposite electrode 230 may be a single layer over the plurality of pixel electrodes 210, which may entirely cover the display area DA.

Although FIG. 3 shows that the sixth semiconductor layer A6 of the sixth transistor T6 is arranged on a layer on which the first semiconductor layer A1 of the first transistor T1 is arranged, one or more embodiments are not limited thereto. In an embodiment, the sixth semiconductor layer A6 of the sixth transistor T6 may be arranged on a layer different from a layer on which the first semiconductor layer A1 of the first transistor T1 is arranged. For example, the sixth transistor T6 may be arranged between the substrate 100 and the first semiconductor layer A1 of the first transistor T1. The sixth semiconductor layer A6 of the sixth transistor T6 may include a silicon semiconductor material. In this regard, the first transistor T1 may be a driving transistor that outputs a driving current corresponding to a data signal, and the sixth transistor T6 may be a switching transistor that is turned on or turned off according to a gate signal.

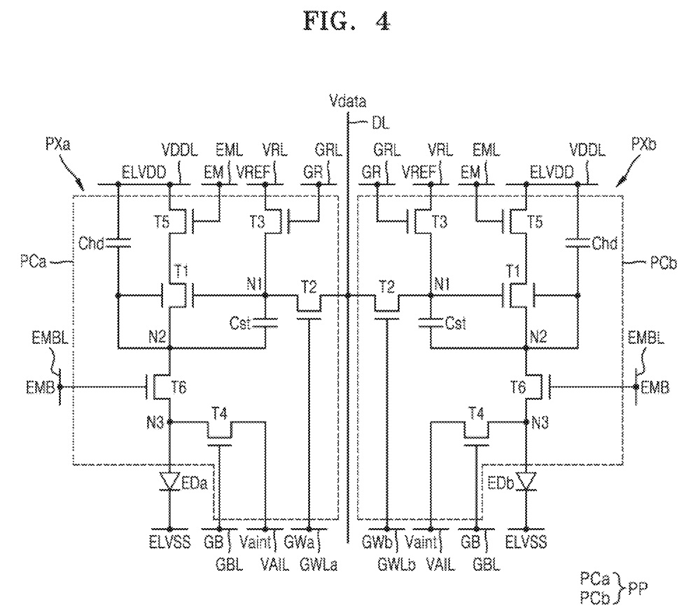

FIG. 4 is an equivalent circuit diagram schematically showing pixels according to an embodiment.

Referring to FIG. 4, one pixel circuit pair PP may be arranged in the same row and may include a first pixel circuit PCa and a second pixel circuit PCb neighboring each other. The first pixel circuit PCa may be electrically connected to a first light-emitting diode EDa to constitute a first pixel PXa. The second pixel circuit PCb may be electrically connected to a second light-emitting diode EDb to constitute a second pixel PXb.

Each of the first pixel circuit PCa and the second pixel circuit PCb may include first to sixth transistors T1, T2, T3, T4, T5, and T6, the storage capacitor Cst, and the hold capacitor Chd. The first transistor T1 may be a driving transistor that outputs a driving current corresponding to a data signal Vdata, and the second to sixth transistors T2 to T6 may be switching transistors that are turned on or turned off according to a gate-source voltage or a gate voltage.

The first to sixth transistors T1 to T6 may be implemented as thin-film transistors. A first terminal and a second terminal of each of the first to sixth transistors T1 to T6 may be source or drain. For example, when the first terminal is the source, the second terminal may be the drain.

The first pixel circuit PCa may be connected to a first gate line GWLa configured to transmit a first gate signal GWa, a third gate line GBL configured to transmit a third gate signal GB, a fourth gate line GRL configured to transmit a fourth gate signal GR, a fifth gate line EML configured to transmit a fifth gate signal EM, a sixth gate line EMBL configured to transmit a sixth gate signal EMB, and a data line DL configured to transmit the data signal Vdata.

The second pixel circuit PCb may be connected to a second gate line GWLb configured to transmit a second gate signal GWb, the third gate line GBL configured to transmit the third gate signal GB, the fourth gate line GRL configured to transmit the fourth gate signal GR, the fifth gate line EML configured to transmit the fifth gate signal EM, the sixth gate line EMBL configured to transmit the sixth gate signal EMB, and the data line DL configured to transmit the data signal Vdata.

In addition, the first pixel circuit PCa and the second pixel circuit PCb may each be connected to a driving voltage line VDDL configured to transfer the first driving voltage ELVDD, a reference voltage line VRL configured to transfer a reference voltage VREF, and an initialization voltage line VAIL configured to transfer an initialization voltage Vaint.

In an embodiment, the first to sixth transistors T1 to T6 may be provided as N-channel MOSFETs (NMOS). In an embodiment, some of the first to sixth transistors T1 to T6 may be provided as N-channel MOSFETs (NMOS), and the others may be provided as P-channel MOSFETs (PMOS). For example, the first transistor T1 may be provided as an N-channel MOSFET (NMOS), and the second to sixth transistors T2 to T6 may be provided as N-channel MOSFETs (NMOS) or P-channel MOSFETs (PMOS) but at least one transistor may be provided as a P-channel MOSFET (PMOS). In an embodiment, the first to fourth transistors T1 to T4 may be provided as N-channel MOSFETs (NMOS), and the fifth transistor T5 and the sixth transistor T6 may be provided as P-channel MOSFETs (PMOS). In an embodiment, the first to sixth transistors T1 to T6 may be provided as P-channel MOSFETs (PMOS).

In an embodiment, the first to sixth transistors T1 to T6 may be oxide semiconductor transistors including an oxide semiconductor material. For example, the oxide semiconductor material may include oxide of at least one material selected from the group including indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and zinc (Zn). The oxide semiconductor material may be IGZO (In-Ga-Zn-O), ITZO (In-Sn-Zn-O), or IGTZO (In-Ga-Sn-Zn-O).

Because an oxide semiconductor has high carrier mobility and low leakage current, a voltage drop is not significant even when a driving time is long. Accordingly, an oxide semiconductor transistor may allow low-frequency driving. In addition, when the oxide semiconductor transistor is used, a crystallization process by excimer laser annealing (ELA) is not required to form a low-temperature polycrystalline silicon (LTPS) semiconductor transistor, and thus, the manufacturing cost of a display apparatus may be reduced.

In an embodiment, some of the first to sixth transistors T1 to T6 may be oxide semiconductor transistors, and the others may be silicon semiconductor transistors including a silicon-based semiconductor material. For example, the first transistor T1 may be an oxide semiconductor transistor, and the second to sixth transistors T2 to T6 may be oxide semiconductor transistors or silicon semiconductor transistors but at least one transistor may be a silicon semiconductor transistor. In an embodiment, the first to fourth transistors T1 to T4 may be oxide semiconductor transistors, and the fifth transistor T5 and the sixth transistor T6 may be silicon semiconductor transistors. In an embodiment, the first to sixth transistors T1 to T6 may be silicon semiconductor transistors. A silicon-based semiconductor material may be polysilicon or amorphous silicon.

In regard to the first pixel PXa, the first transistor T1 (a driving transistor) may include a first terminal connected to the driving voltage line VDDL via the fifth transistor T5, a second terminal connected to a second node N2, and a gate connected to a first node N1. The first transistor T1 of the first pixel circuit PCa may receive the data signal Vdata corresponding to the first pixel PXa according to a switching operation of the second transistor T2 and supply a driving current to the first light-emitting diode EDa.

The second transistor T2 (a data writing transistor) may include a gate connected to the first gate line GWLa, a first terminal connected to the data line DL, and a second terminal connected to the first node N1. The second transistor T2 may be turned on according to the first gate signal GWa received through the first gate line GWLa to perform a switching operation for transmitting the data signal Vdata transmitted through the data line DL to the first node N1.

The third transistor T3 (a first initialization transistor) may include a gate connected to the fourth gate line GRL, a first terminal connected to the reference voltage line VRL, and a second terminal connected to the first node N1. The third transistor T3 may be turned on according to the fourth gate signal GR received through the fourth gate line GRL to transfer the reference voltage VREF transferred through the reference voltage line VRL to the first node N1 and initialize the first node N1.

The fourth transistor T4 (a second initialization transistor) may include a gate connected to the third gate line GBL, a first terminal connected to the initialization voltage line VAIL, and a second terminal connected to a third node N3. The fourth transistor T4 may be turned on according to the third gate signal GB received through the third gate line GBL to transfer the initialization voltage Vaint transferred through the initialization voltage line VAIL to the third node N3 and initialize a pixel electrode of the first light-emitting diode EDa.

The fifth transistor T5 (a first emission control transistor) may include a gate connected to the fifth gate line EML, a first terminal connected to the driving voltage line VDDL, and a second terminal connected to the first terminal of the first transistor T1. The sixth transistor T6 (a second emission control transistor) may include a gate connected to the sixth gate line EMBL, a first terminal connected to the second node N2, and a second terminal connected to the third node N3. The fifth transistor T5 may be turned on according to the fifth gate signal EM received through the fifth gate line EML and the sixth transistor T6 may be turned on according to the sixth gate signal EMB received through the sixth gate line EMBL, and thus, a driving current may flow through the first light-emitting diode EDa.

In an embodiment, the gate of the fifth transistor T5 and the gate of the sixth transistor T6 may be connected to the same gate line (an emission control signal line). In this case, the fifth transistor T5 and the sixth transistor T6 may be turned on simultaneously by the same gate signal (an emission control signal).

The storage capacitor Cst may include a first electrode connected to the first node N1 and a second electrode connected to the second node N2. The storage capacitor Cst is a storage capacitor and may store voltages corresponding to a threshold voltage of the first transistor T1 and the data signal Vdata.

The hold capacitor Chd may include a first electrode connected to the driving voltage line VDDL and a second electrode connected to the second node N2. In some embodiments, the first electrode of the hold capacitor Chd may be electrically connected to a voltage line such as the initialization voltage line VAIL, the reference voltage line VRL, etc. In an embodiment, the display apparatus 10 may further include an auxiliary driving voltage line configured to transfer the second driving voltage ELVSS, and the first electrode of the hold capacitor Chd may be electrically connected to the auxiliary driving voltage line. In an embodiment, capacitance of the storage capacitor Cst may be greater than capacitance of the hold capacitor Chd.

The first light-emitting diode EDa may include a pixel electrode connected to the third node N3, and an opposite electrode (e.g., a cathode) facing the pixel electrode, and the opposite electrode may receive the second driving voltage ELVSS. The opposite electrode may be a common electrode that is common to a plurality of light-emitting diodes.

In regard to the second pixel circuit PCb, the first transistor T1 (a driving transistor) may include a first terminal connected to the driving voltage line VDDL via the fifth transistor T5, a second terminal connected to a second node N2, and a gate connected to a first node N1. The first transistor T1 of the second pixel circuit PCb may receive the data signal Vdata corresponding to the second pixel PXb according to a switching operation of the second transistor T2 and supply a driving current to the second light-emitting diode EDb.

The second transistor T2 (a data writing transistor) may include a gate connected to the second gate line GWLb, a first terminal connected to the data line DL, and a second terminal connected to the first node N1. The second transistor T2 may be turned on according to the second gate signal GWb received through the second gate line GWLb to perform a switching operation for transmitting the data signal Vdata transmitted through the data line DL to the first node N1.

The third transistor T3 (a first initialization transistor) may include a gate connected to the fourth gate line GRL, a first terminal connected to the reference voltage line VRL, and a second terminal connected to the first node N1. The third transistor T3 may be turned on according to the fourth gate signal GR received through the fourth gate line GRL to transfer the reference voltage VREF transferred through the reference voltage line VRL to the first node N1 and initialize the first node N1.

The fourth transistor T4 (a second initialization transistor) may include a gate connected to the third gate line GBL, a first terminal connected to the initialization voltage line VAIL, and a second terminal connected to a third node N3. The fourth transistor T4 may be turned on according to the third gate signal GB received through the third gate line GBL to transfer the initialization voltage Vaint transferred through the initialization voltage line VAIL to the third node N3 and initialize a pixel electrode of the second light-emitting diode EDb.

The fifth transistor T5 (a first emission control transistor) may include a gate connected to the fifth gate line EML, a first terminal connected to the driving voltage line VDDL, and a second terminal connected to the first terminal of the first transistor T1. The sixth transistor T6 (a second emission control transistor) may include a gate connected to the sixth gate line EMBL, a first terminal connected to the second node N2, and a second terminal connected to the third node N3. The fifth transistor T5 may be turned on according to the fifth gate signal EM received through the fifth gate line EML and the sixth transistor T6 may be turned on according to the sixth gate signal EMB received through the sixth gate line EMBL, and thus, a driving current may flow through the second light-emitting diode EDb.

The storage capacitor Cst may include a first electrode connected to the first node N1 and a second electrode connected to the second node N2. The storage capacitor Cst is a storage capacitor and may store voltages corresponding to a threshold voltage of the first transistor T1 and the data signal Vdata.

The hold capacitor Chd may include a first electrode connected to the driving voltage line VDDL and a second electrode connected to the second node N2. In an embodiment, capacitance of the storage capacitor Cst may be greater than capacitance of the hold capacitor Chd.

The second light-emitting diode EDb may include a pixel electrode connected to the third node N3, and an opposite electrode (e.g., a cathode) facing the pixel electrode, and the opposite electrode may receive the second driving voltage ELVSS. The opposite electrode may be a common electrode that is common to a plurality of light-emitting diodes.

The second gate signal GWb may be output phase-delayed (shifted) by a certain period from the first gate signal GWa . For example, the second gate signal GWb may be output delayed by 0.5 horizontal period (0.5H) from the first gate signal GWa. Accordingly, the second transistor T2 of the first pixel circuit PCa may be turned on first and then the second transistor T2 of the second pixel circuit PCb may be turned on, and the second transistor T2 of the first pixel circuit PCa may be turned off first and then the second transistor T2 of the second pixel circuit PCb may be turned off. Accordingly, the data signal Vdata supplied through one data line DL may be supplied in a time-division manner to the first pixel circuit PCa and the second pixel circuit PCb. As two pixel circuits constituting the pixel circuit pair PP share one data line DL, the number of data lines DL may be reduced, and thus, the manufacturing cost of the display apparatus 10 may be reduced.

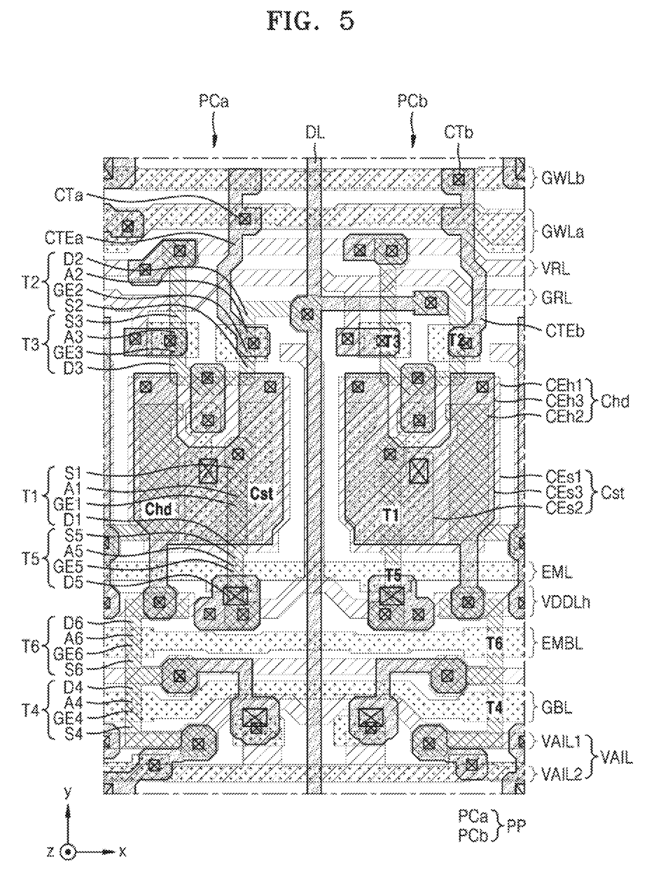

FIG. 5 is a schematic plan view of pixel circuits according to an embodiment.

Referring to FIG. 5, one pixel circuit pair PP may include the first pixel circuit PCa and the second pixel circuit PCb electrically connected to the same data line DL. The first pixel circuit PCa may be a pixel circuit electrically connected to the first gate line GWLa, and the second pixel circuit PCb may be a pixel circuit electrically connected to the second gate line GWLb. The first pixel circuit PCa and the second pixel circuit PCb may neighbor each other in a first direction (a direction x), and the data line DL may be arranged between the first pixel circuit PCa and the second pixel circuit PCb and may extend in a second direction (a direction y).

Although FIG. 5 shows that the first pixel circuit PCa is left (e.g., in a direction -x) to the data line DL and the second pixel circuit PCb is right (e.g., in a direction +x) to the data line DL in a plan view, one or more embodiments are not limited thereto. When the pixel circuit pair PP shown in FIG. 5 is positioned in an m-th pixel circuit row, the first pixel circuit PCa of a pixel circuit pair positioned in a (m+1)-th pixel circuit row may be right (e.g., in the direction +x) to the data line DL, and the second pixel circuit PCb may be left (e.g., in the direction -x) to the data line DL. In this regard, m may be a natural number of 1 or greater.

Each of the first pixel circuit PCa and the second pixel circuit PCb may include first to sixth transistors T1, T2, T3, T4, T5, and T6, the storage capacitor Cst, and the hold capacitor Chd. The first pixel circuit PCa may be connected to the first gate line GWLa, the third gate line GBL, the fourth gate line GRL, the fifth gate line EML, the sixth gate line EMBL, and the data line DL. The second pixel circuit PCb may be connected to the second gate line GWLb, the third gate line GBL, the fourth gate line GRL, the fifth gate line EML, the sixth gate line EMBL, and the data line DL. The second gate line GWLb, the third gate line GBL, the fourth gate line GRL, the fifth gate line EML, and the sixth gate line EMBL may extend in the first direction (the direction x). In addition, the first pixel circuit PCa and the second pixel circuit PCb may each be electrically connected to the reference voltage line VRL, a horizontal driving voltage line VDDLh, and the initialization voltage line VAIL. The first transistors T1 and the fourth to sixth transistors T4 to T6 of the first pixel circuit PCa and the second pixel circuit PCb may be substantially symmetrical with respect to the data line DL. Unless otherwise stated, each element is described below based on the first pixel circuit PCa.

The first transistor T1 may include the first semiconductor layer A1 and the first gate electrode GE1 overlapping the first semiconductor layer A1 in a plan view. The first semiconductor layer A1 may include a channel region and the source region S1 and the drain region D1 arranged at both sides of the channel region.

The first gate electrode GE1 of the first transistor T1 may be integrally formed with the second electrode CEs2 of the storage capacitor Cst. The second electrode CEs2 of the storage capacitor Cst may overlap the first electrode CEs1 and the third electrode CEs3 of the storage capacitor Cst in a plan view.

The second transistor T2 may include a second semiconductor layer A2 and a second gate electrode GE2 overlapping the second semiconductor layer A2 in a plan view. The second semiconductor layer A2 may include a channel region and a source region S2 and a drain region D2 arranged at both sides of the channel region. The source region S2 of the second transistor T2 may be electrically connected to the first gate electrode GE1 of the first transistor T1 and a drain region D3 of the third transistor T3 through a connection electrode. The drain region D2 of the second transistor T2 may be electrically connected to the data line DL.

The second gate electrode GE2 of the second transistor T2 may have an isolated shape (i.e., an island shape) in a plan view. In the first pixel circuit PCa, the second gate electrode GE2 of the second transistor T2 may be electrically connected to the first gate line GWLa through a fourth connection electrode CTEa. The fourth connection electrode CTEa may overlap the first gate line GWLa and the second gate line GWLb but may be connected to the first gate line GWLa through a contact hole CTa penetrating an insulating layer (e.g., the first insulating layer 115 (refer to FIG. 3)). The fourth connection electrode CTEa and the second gate line GWLb may be electrically separated by at least one insulating layer.

In the second pixel circuit PCb, the second gate electrode GE2 of the second transistor T2 may be electrically connected to the second gate line GWLb through a fifth connection electrode CTEb. The fifth connection electrode CTEb may overlap the first gate line GWLa and the second gate line GWLb but may be connected to the second gate line GWLb through a contact hole CTb penetrating an insulating layer (e.g., the first insulating layer 115). The fifth connection electrode CTEb and the first gate line GWLa may be electrically separated by at least one insulating layer.

The third transistor T3 may include a third semiconductor layer A3 and a third gate electrode GE3 overlapping the third semiconductor layer A3 in a plan view. The third semiconductor layer A3 of the third transistor T3 and the second semiconductor layer A2 of the second transistor T2 may be integrally formed with each other.

The third semiconductor layer A3 may include a channel region and a source region S3 and the drain region D3 arranged at both sides of the channel region. The drain region D3 of the third transistor T3 may be electrically connected to the first gate electrode GE1 of the first transistor T1 and the source region S2 of the second transistor T2 through a connection electrode. The source region S3 of the third transistor T3 may be electrically connected to the reference voltage line VRL.

The third gate electrode GE3 of the third transistor T3 may have an isolated shape in a plan view. The third gate electrode GE3 of the third transistor T3 may be electrically connected to the fourth gate line GRL through a connection electrode.

The fourth transistor T4 may include a fourth semiconductor layer A4 and a fourth gate electrode GE4 overlapping the fourth semiconductor layer A4 in a plan view. The fourth semiconductor layer A4 may include a channel region and a source region S4 and a drain region D4 arranged at both sides of the channel region. The source region S4 of the fourth transistor T4 may be electrically connected to the initialization voltage line VAIL.

In an embodiment, the initialization voltage line VAIL may include a first initialization voltage line VAIL1 and a second initialization voltage line VAIL2. Depending on a color of light emitted by an organic light-emitting diode connected to a pixel circuit, the pixel circuit may be selectively connected to the first initialization voltage line VAIL1 or the second initialization voltage line VAIL2. For example, when the organic light-emitting diode connected to the pixel circuit emits light of a first color, the pixel circuit may be electrically connected to the first initialization voltage line VAIL1 and may receive a first initialization voltage. When the organic light-emitting diode connected to the pixel circuit emits light of a second color, the pixel circuit may be electrically connected to the second initialization voltage line VAIL2 and may receive a second initialization voltage different from the first initialization voltage. In an embodiment, the first color may be blue or green, and the second color may be red. In this regard, FIG. 5 shows the first pixel circuit PCa and the second pixel circuit PCb each electrically connected to the second initialization voltage line VAIL2.

The drain region D4 of the fourth transistor T4 may be electrically connected to the source region S6 of the sixth transistor T6 and a pixel electrode of an organic light-emitting diode. The fourth gate electrode GE4 of the fourth transistor T4 may be a portion of the third gate line GBL. In other words, the fourth gate electrode GE4 of the fourth transistor T4 may be integrally formed with the third gate line GBL.

The fifth transistor T5 may include a fifth semiconductor layer A5 and a fifth gate electrode GE5 overlapping the fifth semiconductor layer A5 in a plan view. In an embodiment, the first semiconductor layer A1 and the fifth semiconductor layer A5 may be integrally formed with each other. The fifth semiconductor layer A5 may include a channel region and a source region S5 and a drain region D5 arranged at both sides of the channel region. The source region S5 of the fifth transistor T5 may be connected to the drain region D1 of the first transistor T1. The drain region D5 of the fifth transistor T5 may be electrically connected to the horizontal driving voltage line VDDLh. In an embodiment, the horizontal driving voltage line VDDLh, which is a portion of the driving voltage line VDDL (refer to FIG. 4), may be electrically connected to a vertical driving voltage line through a connection electrode and may be configured to transfer the first driving voltage ELVDD (refer to FIG. 4).

The fifth gate electrode GE5 of the fifth transistor T5 may be a portion of the fifth gate line EML. For example, the fifth gate electrode GE5 of the fifth transistor T5 may be integrally formed with the fifth gate line EML.

The sixth transistor T6 may include the sixth semiconductor layer A6 and the sixth gate electrode GE6 overlapping the sixth semiconductor layer A6 in a plan view. The sixth semiconductor layer A6 of the sixth transistor T6 and the fourth semiconductor layer A4 of the fourth transistor T4 may be integrally formed with each other.

The sixth semiconductor layer A6 may include a channel region and the source region S6 and the drain region D6 arranged at both sides of the channel region. The source region S6 of the sixth transistor T6 may be electrically connected to the drain region D4 of the fourth transistor T4 and the pixel electrode of the organic light-emitting diode. The drain region D6 of the sixth transistor T6 may be electrically connected to the source region S1 of the first transistor T1, the storage capacitor Cst, and the hold capacitor Chd through the third electrode CEs3 of the storage capacitor Cst. The sixth gate electrode GE6 of the sixth transistor T6 may be a portion of the sixth gate line EMBL. In other words, the sixth gate electrode GE6 of the sixth transistor T6 may be integrally formed with the sixth gate line EMBL.

The hold capacitor Chd may include the first electrode CEh1, the second electrode CEh2, and the third electrode CEh3 overlapping one another in a plan view. The first electrode CEh1 of the hold capacitor Chd may be integrally formed with the first electrode CEs1 of the storage capacitor Cst, and the third electrode CEh3 of the hold capacitor Chd may be integrally formed with the third electrode CEs3 of the storage capacitor Cst. The second electrode CEh2 of the hold capacitor Chd may be apart from the second electrode CEs2 of the storage capacitor Cst in a plan view.

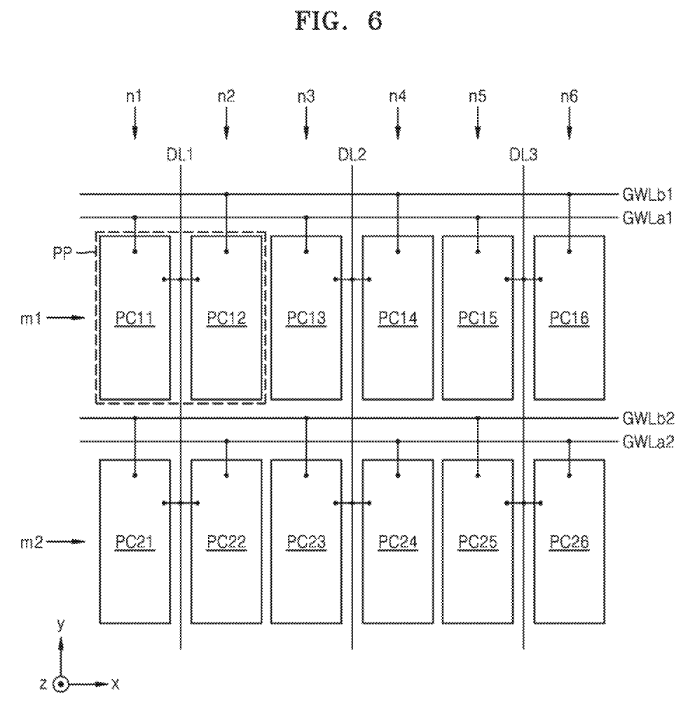

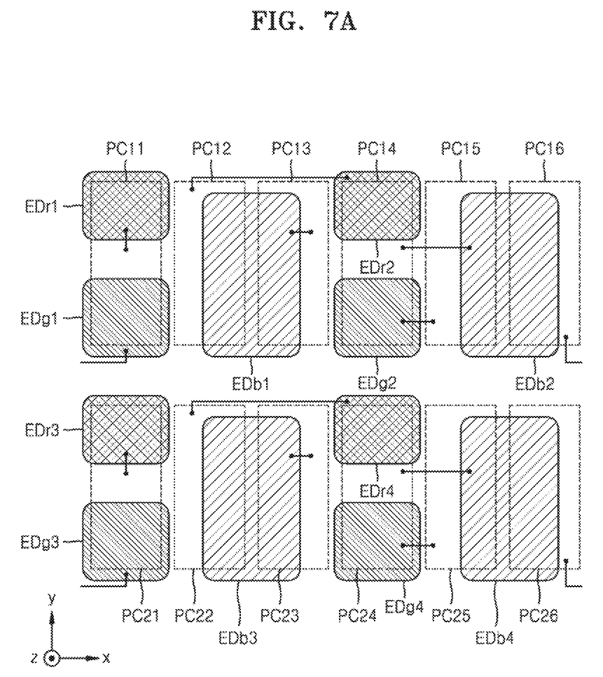

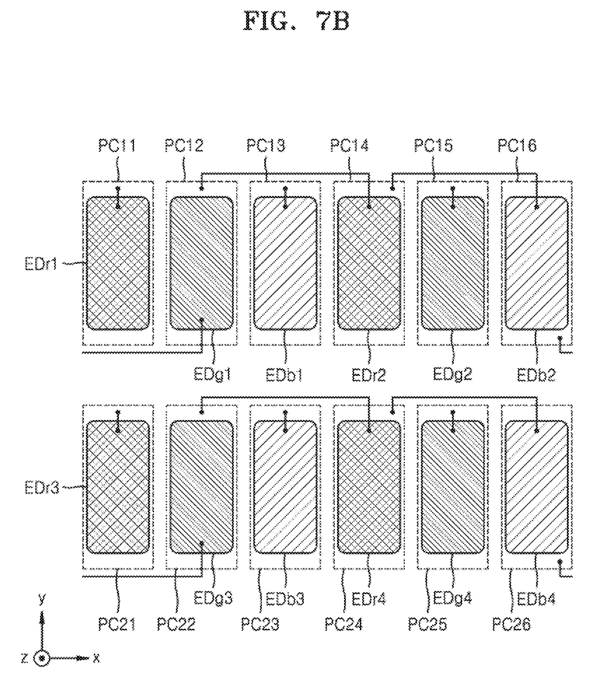

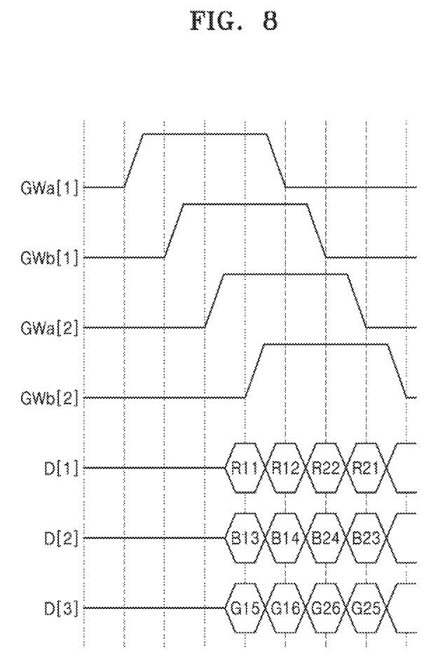

FIG. 6 is a diagram for schematically describing a connection between pixel circuits and data lines and gate lines, according to an embodiment. FIGS. 7A and 7B are diagrams for schematically describing a connection between the pixel circuits shown in FIG. 6 and light-emitting diodes. FIG. 8 is a diagram for describing gate voltages and data voltages that are applied to the pixel circuits shown in FIG. 6.

Referring to FIG. 6, pixel circuits PCmn may be arranged in a matrix in a first direction (a direction x) and a second direction (a direction y) crossing the first direction (the direction x). In this regard, m indicates a pixel circuit row where a pixel circuit is positioned, and n indicates a pixel circuit column where the pixel circuit is positioned. In this regard, each of m and n is a natural number of 1 or greater. Although FIG. 6 shows an extract of twelve pixel circuits PC11, PC12, ..., PC26 arranged in a 2×6 matrix, one or more embodiments are not limited thereto. The display apparatus 10 may include more pixel circuits PCmn and signal lines.

First gate lines may include a first first gate line GWLa1 and a second first gate line GWLa2 extending in the first direction (the direction x). Second gate lines may include a first second gate line GWLb1 and a second second gate line GWLb2 extending in the first direction (the direction x). Data lines may include a first data line DL1, a second data line DL2, and a third data line DL3 each extending in the second direction (the direction y). Each of the pixel circuits PCmn may be electrically connected to a corresponding one of the data lines and a corresponding one of the first gate lines and the second gate lines.

A pair of pixel circuit columns neighboring each other in the first direction (the direction x) may be electrically connected to one corresponding data line. For example, the pixel circuits PC11 and PC21 arranged in a first pixel circuit column n1 and the pixel circuits PC12 and PC22 arranged in a second pixel circuit column n2 may be electrically connected to the first data line DL1. The pixel circuits PC13 and PC23 arranged in a third pixel circuit column n3 and the pixel circuits PC14 and PC24 arranged in a fourth pixel circuit column n4 may be electrically connected to the second data line DL2. The pixel circuits PC15 and PC25 arranged in a fifth pixel circuit column n5 and the pixel circuits PC16 and PC26 arranged in a sixth pixel circuit column n6 may be electrically connected to the third data line DL3.

A pixel circuit arranged in an odd-numbered pixel circuit column and a pixel circuit arranged in an even-numbered pixel circuit column that are electrically connected to one data line and neighbor each other in the first direction (the direction x) may be defined as a pixel circuit pair PP. One of the two pixel circuits constituting the pixel circuit pair PP may be electrically connected to a corresponding first gate line, and the other may be electrically connected to a corresponding second gate line.

The pixel circuits PC11, PC13, and PC15 arranged in odd-numbered pixel circuit columns (also referred to as odd-numbered columns for short) of an odd-numbered pixel circuit row m1 (also referred to as odd-numbered row for short) among the pixel circuits PCmn may be electrically connected to the first first gate line GWLa1, and the pixel circuits PC22, PC24, and PC26 arranged in even-numbered pixel circuit columns (also referred to as even-numbered columns for short) of an even-numbered pixel circuit row m2 (also referred to as even-numbered row for short) may be electrically connected to the second first gate line GWLa2. The pixel circuits PC12, PC14, and PC16 arranged in even-numbered pixel circuit columns of the odd-numbered pixel circuit row m1 among the pixel circuits PCmn may be electrically connected to the first second gate line GWLb1, and the pixel circuits PC21, PC23, and PC25 arranged in odd-numbered pixel circuit columns of the even-numbered pixel circuit row m2 may be electrically connected to the second second gate line GWLb2.

Referring to FIGS. 7A and 7B, each of the pixel circuits PCmn may be electrically connected to a corresponding light-emitting diode. The boundaries of light-emitting diodes EDr1, EDg1, EDb1, ..., EDr4, EDg4, EDb4 shown in FIGS. 7A and 7B schematically show the boundaries of emission areas of each light-emitting diode.

Referring to FIG. 7A, light-emitting diodes EDr1, EDg1, EDb1, ..., EDr4, EDg4, EDb4 may be arranged in a first direction (a direction x) and a second direction (a direction y). The red light-emitting diodes EDr1, EDr2, EDr3, and EDr4 emitting red light and the green light-emitting diodes EDg1, EDg2, EDg3, and EDg4 emitting green light may alternate with each other in odd-numbered light-emitting diode columns, and the blue light-emitting diodes EDb1, EDb2, EDb3, and EDb4 emitting blue light may be arranged in even-numbered light-emitting diode columns. The light-emitting diodes EDr1, EDg1, EDb1, ..., EDr4, EDg4, EDb4 may be arranged in a stripe arrangement.

Referring to FIG. 7B, the light-emitting diodes EDr1, EDg1, EDb1, ..., EDr4, EDg4, EDb4 may be arranged in the first direction (the direction x) and the second direction (the direction y). A column of the red light-emitting diodes EDr1, EDr2, EDr3, and EDr4 arranged in the second direction (the direction y), a column of the green light-emitting diodes EDg1, EDg2, EDg3, and EDg4 arranged in the second direction (the direction y), and a column of the blue light-emitting diodes EDb1, EDb2, EDb3, and EDb4 arranged in the second direction (the direction y) may be sequentially repeated in the first direction (the direction x). Within a repeating unit, the arrangement order of a column in which red light-emitting diodes are arranged, a column in which green light-emitting diodes are arranged, and a column in which blue light-emitting diodes are arranged may vary.

The light-emitting diodes EDr1, EDg1, EDb1, ..., EDr4, EDg4, EDb4 may be electrically connected to corresponding data lines through corresponding pixel circuits. Light-emitting diodes electrically connected to the same data line may emit light of the same color. For example, the first red light-emitting diode EDr1 may be electrically connected to the [1,1]th pixel circuit PC11, the second red light-emitting diode EDr2 may be electrically connected to the [1,2]th pixel circuit PC12, the third red light-emitting diode EDr3 may be electrically connected to the [2,1]th pixel circuit PC21, and the fourth red light-emitting diode EDr4 may be electrically connected to the [2,2]th pixel circuit PC22. The [1,1]th pixel circuit PC11, the [1,2]th pixel circuit PC12, the [2,1]th pixel circuit PC21,and the [2,2]th pixel circuit PC22 may be electrically connected to the first data line DL1. The first to fourth red light-emitting diodes EDr1, EDr2, EDr3, and EDr4 may emit red light.

Likewise, the first blue light-emitting diode EDb1 may be electrically connected to the [1,3]th pixel circuit PC13, the second blue light-emitting diode EDb2 may be electrically connected to the [1,4]th pixel circuit PC14, the third blue light-emitting diode EDb3 may be electrically connected to the [2,3]th pixel circuit PC23, and the fourth blue light-emitting diode EDb4 may be electrically connected to the [2,4]th pixel circuit PC24. The first to fourth blue light-emitting diodes EDb1, EDb2, EDb3, and EDb4 may each be electrically connected to the second data line DL2 and may emit blue light.

The second green light-emitting diode EDg2 may be electrically connected to the [1,5]th pixel circuit PC15, and the fourth green light-emitting diode EDg4 may be electrically connected to the [2,5]th pixel circuit PC25. Each of the first green light-emitting diode EDg1 and the third green light-emitting diode EDg3 may be electrically connected to a pixel circuit arranged on the left (in a direction -x). Each of the [1,6]th pixel circuit PC16 and the [2,6]th pixel circuit PC26 may be electrically connected to a green light-emitting diode arranged on the right. The second and fourth green light-emitting diodes EDg2 and EDg4 may each be electrically connected to the third data line DL3 and may emit green light.

Accordingly, a data signal transmitted by each of the data lines DL1, DL2, and DL3 may include only data voltages for driving pixels that emit light of the same color, and thus, the display apparatus 10 may reduce power consumption due to changes in data voltage.

A distance between the [1,1]th pixel circuit PC11 and the first red light-emitting diode EDr1 may be different from a distance between the [1,2]th pixel circuit PC12 and the second red light-emitting diode EDr2. For example, the first red light-emitting diode EDr1 may overlap the [1,1]th pixel circuit PC11 in a plan view, and the second red light-emitting diode EDr2 may be apart from the [1,2]th pixel circuit PC12 in a plan view.

Referring to FIG. 8, a first first gate signal GWa[1] may be transmitted to the first first gate line GWLa1, a second first gate signal GWa[2] may be transmitted to the second first gate line GWLa2, a first second gate signal GWb[1] may be transmitted to the first second gate line GWLb1, and a second second gate signal GWb[2] may be transmitted to the second second gate line GWLb2. The gate signals GWa[1], GWa[2], GWb[1], and GWb[2] may be supplied as square wave signals in which an on voltage at which the connected second transistors T2 (refer to FIG. 4) may be turned on and an off voltage at which the connected second transistors T2 (refer to FIG. 4) may be turned off are repeatedly output. In an embodiment, an on voltage of the second transistors T2 may be a high-level voltage, and an off voltage of the second transistors T2 may be a low-level voltage.

The first gate driver 12 (refer to FIG. 2) may be configured to sequentially supply the first gate signals GWa[1] and GWa[2] to the first gate lines GWLa1 and GWLa2. The second first gate signal GWa[2] may be output phase-delayed by 1 horizontal period (1H) from the first first gate signal GWa[1].

The second gate driver 13 (refer to FIG. 2) may be configured to sequentially supply the second gate signals GWb[1] and GWb[2] to the second gate lines GWLb1 and GWLb2. The first second gate signal GWb[1] may be output phase-delayed by a certain period from the first first gate signal GWa[1]. For example, the first second gate signal GWb[1] may be output phase-delayed by 0.5 horizontal period (0.5H) from the first first gate signal GWa[1]. The second second gate signal GWb[2] may be output phase-delayed by 1 horizontal period (1H) from the first second gate signal GWb[1].

The data driver 15 (refer to FIG. 2) may be configured to supply a first data signal D[1] to the first data line DL1, supply a second data signal D[2] to the second data line DL2, and supply a third data signal D[3] to the third data line DL3. The first data signal D[1] may include a red data voltage R11 corresponding to the [1,1]th pixel circuit PC11, a red data voltage R12 corresponding to the [1,2]th pixel circuit PC12, a red data voltage R22 corresponding to the [2,2]th pixel circuit PC22, and a red data voltage R21 corresponding to the [2,1]th pixel circuit PC21, which are sequentially output. The second data signal D[2] may include a blue data voltage B13 corresponding to the [1,3]th pixel circuit PC13, a blue data voltage B14 corresponding to the [1,4]th pixel circuit PC14, a blue data voltage B24 corresponding to the [2,4]th pixel circuit PC24, and a blue data voltage B23 corresponding to the [2,3]th pixel circuit PC23, which are sequentially output. The third data signal D[3] may include a green data voltage G15 corresponding to the [1,5]th pixel circuit PC15, a green data voltage G16 corresponding to the [1,6]th pixel circuit PC16, a green data voltage G26 corresponding to the [2,6]th pixel circuit PC26, and a green data voltage G25 corresponding to the [2,5]th pixel circuit PC25, which are sequentially output.

In other words, each of the data signals D[1], D[2], and D[3] may sequentially output a data voltage corresponding to the pixel circuits PC11, PC13, and PC15 connected to the first first gate line GWLa1, a data voltage corresponding to the pixel circuits PC12, PC14, and PC16 connected to the first second gate line GWLb1, a data voltage corresponding to the pixel circuits PC22, PC24, and PC26 connected to the second first gate line GWLa2, and a data voltage corresponding to the pixel circuits PC21, PC23, and PC25 connected to the second second gate line GWLb2.

Accordingly, the data signals D[1], D[2], and D[3] respectively transmitted by the data lines DL1, DL2, and DL3 may include only data voltages for driving pixels that emit light of the same color, and thus, power consumption for data voltage toggling may be reduced.

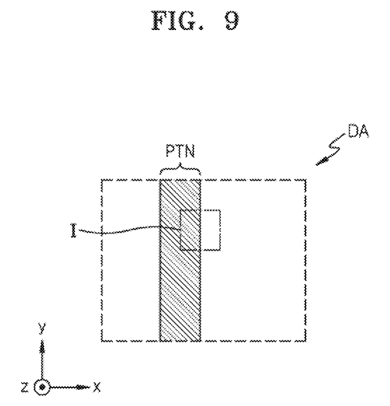

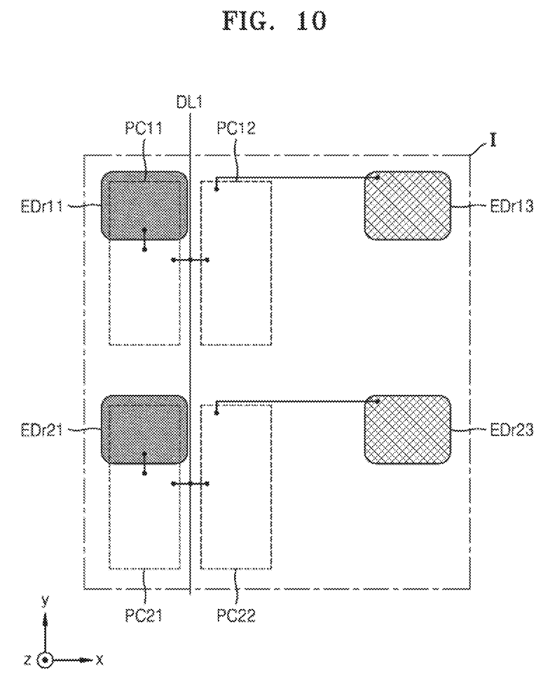

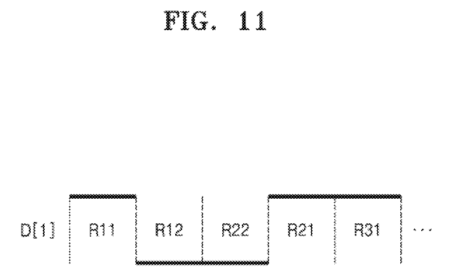

FIG. 9 is a schematic plan view of a portion of a display apparatus according to an embodiment. FIG. 10 is a diagram for schematically describing operations of pixel circuits and light-emitting diodes of the display apparatus of FIG. 9. FIG. 11 is a schematic diagram of a data voltage that is applied to a first data line of the display apparatus of FIG. 9.

FIG. 9 shows the display apparatus 10 (refer to FIG. 1A) displaying an image pattern PTN extending in a second direction (a direction y) in the display area DA. The pixel unit 11 (refer to FIG. 2) may be provided in the display area DA, and the image pattern PTN may be implemented by a luminance difference between a plurality of pixels.

FIG. 10 is an enlarged view of a region I of FIG. 9. FIG. 10 shows an extract of the pixel circuits PC11, PC12, PC21, and PC22 electrically connected to the first data line DL1 and red light-emitting diodes EDr11, EDr13, EDr21, and EDr23 by way of example. The region I may include a boundary of the image pattern PTN extending in a second direction (a direction y).

Referring to FIG. 10, the first red light-emitting diode EDr11 may be electrically connected to the [1,1]th pixel circuit PC11, the third red light-emitting diode EDr13 may be electrically connected to the [1,2]th pixel circuit PC12, the second red light-emitting diode EDr21 may be electrically connected to the [2,1]th pixel circuit PC21, and the fourth red light-emitting diode EDr23 may be electrically connected to the [2,2]th pixel circuit PC22. At the boundary of the image pattern PTN extending in the second direction (the direction y), the luminance of light-emitting diodes arranged in the same light-emitting diode column may be the same, and the luminance of light-emitting diodes arranged in different light-emitting diode columns may be different. For example, the first red light-emitting diode EDr11 and the second red light-emitting diode EDr21 arranged in a first light-emitting diode column (refer to FIG. 6) may emit light at a first luminance, and the third red light-emitting diode EDr13 and the fourth red light-emitting diode EDr23 arranged in a third light-emitting diode column (refer to FIG. 6) may emit light at a second luminance different from the first luminance.

Referring to FIG. 11, the first data signal D[1] supplied to the first data line DL1 may include the red data voltage R11 corresponding to the [1,1]th pixel circuit PC11, the red data voltage R12 corresponding to the [1,2]th pixel circuit PC12, the red data voltage R22 corresponding to the [2,2]th pixel circuit PC22, and the red data voltage R21 corresponding to the [2,1]th pixel circuit PC21, which are sequentially output. As shown in FIGS. 9 and 10, at the boundary of the image pattern PTN extending in the second direction (the direction y), the data voltage R11 corresponding to the [1,1]th pixel circuit PC11 and the data voltage R21 corresponding to the [2,1]th pixel circuit PC21 may have the magnitude corresponding to the first luminance, and the data voltage R12 corresponding to the [1,2]th pixel circuit PC12 and the data voltage R22 corresponding to the [2,2]th pixel circuit PC22 may have the magnitude corresponding to the second luminance.

In the display apparatus 10 according to one or more embodiments, as the pixel circuit PC11 arranged in an odd-numbered pixel circuit column of an odd-numbered pixel circuit row and the pixel circuit PC22 arranged in an even-numbered pixel circuit column of an even-numbered pixel circuit row are electrically connected to the corresponding first gate lines GWLa1, GWLa2, and the pixel circuit PC12 arranged in an even-numbered pixel circuit column of the odd-numbered pixel circuit row and the pixel circuit PC21 arranged in an odd-numbered pixel circuit column of the even-numbered pixel circuit row are electrically connected to the corresponding second gate lines GWLb1, GWLb2, data voltages having the same magnitude may be continuously output. Accordingly, the display apparatus 10 according to one or more embodiments may reduce the number of times a data voltage changes. That is, the red data voltage R12 corresponding to the [1,2]th pixel circuit PC12 and the red data voltage R22 corresponding to the [2,2]th pixel circuit PC22 have the same magnitude, which requires no change in data voltage. Likewise, the red data voltage R21 corresponding to the [2,1]th pixel circuit PC21 and a red data voltage R31 corresponding to a [3,1]th pixel circuit have the same magnitude, which requires no change in data voltage.

In an embodiment, in a display apparatus according to a comparative example, in all pixel circuit rows, pixel circuits arranged in odd-numbered pixel circuit columns may each be electrically connected to a corresponding first gate line, and pixel circuits arranged in even-numbered pixel circuit columns may each be electrically connected to a corresponding second gate line. In this case, a data voltage may change for each pixel circuit, and power consumption may increase due to the change in data voltage.

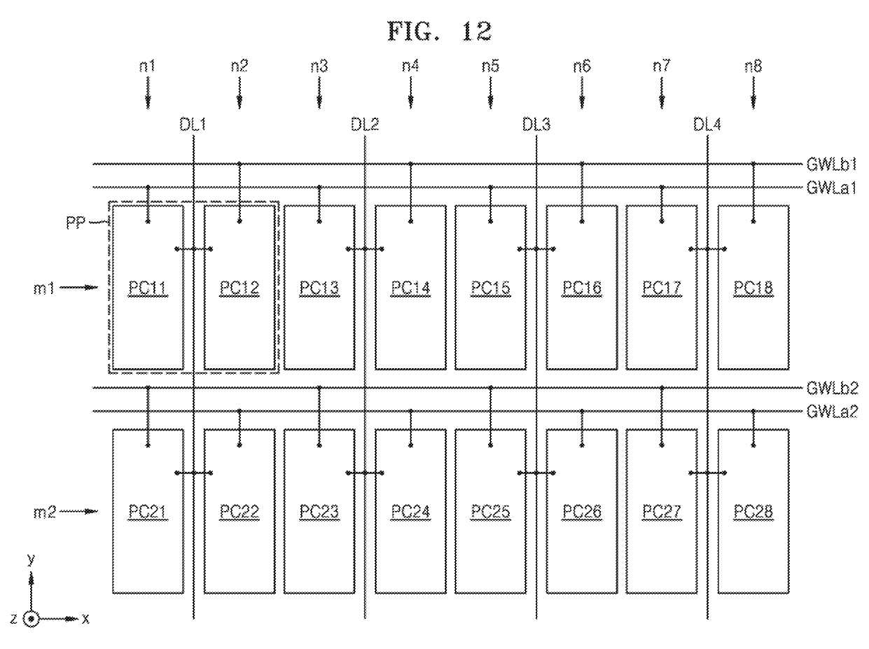

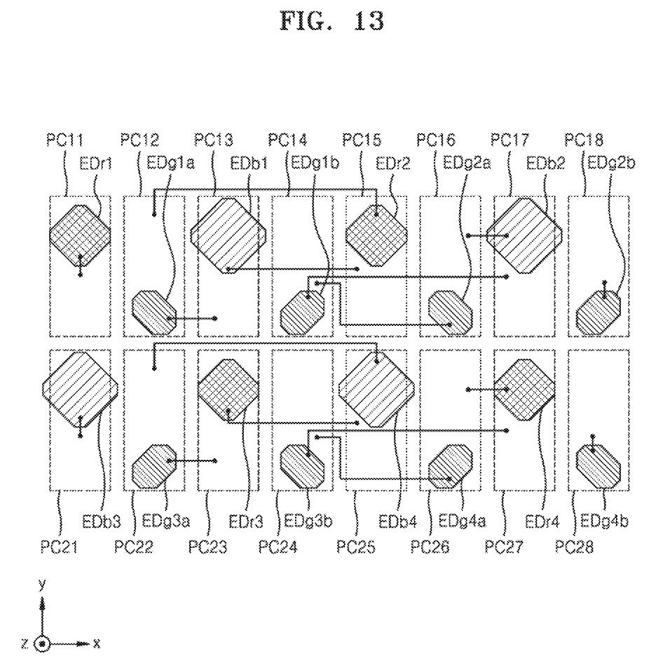

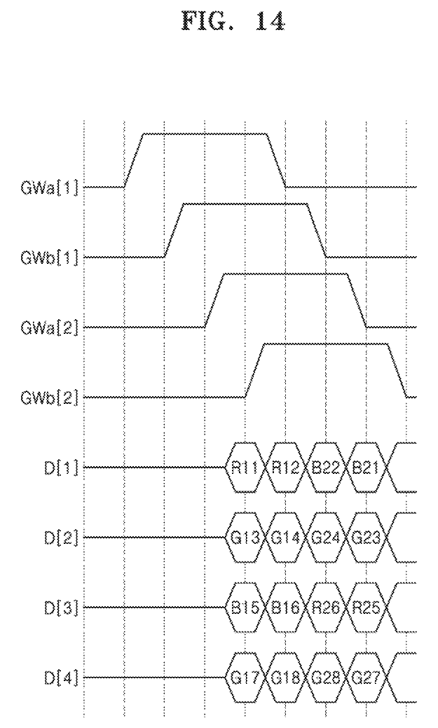

FIG. 12 is a diagram for schematically describing a connection between pixel circuits and data lines and gate lines, according to an embodiment. FIG. 13 is a diagram for schematically describing a connection between the pixel circuits shown in FIG. 12 and light-emitting diodes. FIG. 14 is a diagram for describing gate voltages and data voltages that are applied to the pixel circuits shown in FIG. 12.

Referring to FIG. 12, pixel circuits PCmn may be arranged in a matrix in a first direction (a direction x) and a second direction (a direction y). In this regard, m indicates a pixel circuit row where a pixel circuit is positioned, and n indicates a pixel circuit column where the pixel circuit is positioned. In this regard, each of m and n is a natural number of 1 or greater. Although FIG. 12 shows an extract of sixteen pixel circuits PC11, PC12, ..., PC28 arranged in a 2×8 matrix, one or more embodiments are not limited thereto. The display apparatus 10 may include more pixel circuits PCmn and signal lines.

First gate lines may include the first first gate line GWLa1 and the second first gate line GWLa2 extending in the first direction (the direction x). Second gate lines may include the first second gate line GWLb1 and the second second gate line GWLb2 extending in the first direction (the direction x). Data lines may include the first data line DL1, the second data line DL2, the third data line DL3, and a fourth data line DL4 each extending in the second direction (the direction y). Each of the pixel circuits PCmn may be electrically connected to a corresponding one of the data lines and a corresponding one of the first gate lines and the second gate lines.

A pair of pixel circuit columns neighboring each other in the first direction (the direction x) may be electrically connected to one corresponding data line. For example, the pixel circuits PC11 and PC21 arranged in a first pixel circuit column n1 and the pixel circuits PC12 and PC22 arranged in a second pixel circuit column n2 may be electrically connected to the first data line DL1. The pixel circuits PC13 and PC23 arranged in a third pixel circuit column n3 and the pixel circuits PC14 and PC24 arranged in a fourth pixel circuit column n4 may be electrically connected to the second data line DL2. The pixel circuits PC15 and PC25 arranged in a fifth pixel circuit column n5 and the pixel circuits PC16 and PC26 arranged in a sixth pixel circuit column n6 may be electrically connected to the third data line DL3. The pixel circuits PC17 and PC27 arranged in a seventh pixel circuit column n7 and the pixel circuits PC18 and PC28 arranged in an eighth pixel circuit column n8 may be electrically connected to the fourth data line DL4.

One of the two pixel circuits constituting the pixel circuit pair PP may be electrically connected to a corresponding first gate line, and the other may be electrically connected to a corresponding second gate line. The pixel circuits PC11, PC13, PC15, and PC17 arranged in odd-numbered pixel circuit columns of an odd-numbered pixel circuit row m1 among the pixel circuits PCmn may be electrically connected to the first first gate line GWLa1, and the pixel circuits PC22, PC24, PC26, and PC28 arranged in even-numbered pixel circuit columns of an even-numbered pixel circuit row m2 may be electrically connected to the second first gate line GWLa2. The pixel circuits PC12, PC14, PC16, and PC18 arranged in even-numbered pixel circuit columns of the odd-numbered pixel circuit row m1 among the pixel circuits PCmn may be electrically connected to the first second gate line GWLb1, and the pixel circuits PC21, PC23, PC25, and PC27 arranged in odd-numbered pixel circuit columns of the even-numbered pixel circuit row m2 may be electrically connected to the second second gate line GWLb2.

Referring to FIG. 13, each of the pixel circuits PCmn may be electrically connected to a light-emitting diode. The boundaries of light-emitting diodes EDr1, EDg1a, EDb1, EDg1b, ..., EDb4, EDg4a, EDr4, EDg4b shown in FIG. 13 schematically show the boundaries of emission areas of each light-emitting diode. The light-emitting diodes EDr1, EDg1a, EDb1, EDg1b, ..., EDb4, EDg4a, EDr4, EDg4b may be arranged in a first direction (a direction x) and a second direction (a direction y). The red light-emitting diodes EDr1, EDr2, EDr3, and EDr4 and the blue light-emitting diodes EDb1, EDb2, EDb3, and EDb4 may alternate with each other in odd-numbered light-emitting diode columns, and the green light-emitting diodes EDg1a, EDg1b, EDg2a, EDg2b, EDg3a, EDg3b, EDg4a, and EDg4b may be arranged in even-numbered light-emitting diode columns. In an embodiment, a green light-emitting diode may be arranged at each of the four corners of a virtual quadrilateral, and a blue light-emitting diode or a red light-emitting diode may be arranged at a center of the virtual quadrilateral. The light-emitting diodes EDr1, EDg1a, EDb1, EDg1b, ..., EDb4, EDg4a, EDr4, EDg4b may be arranged in a PenTile^{TM} arrangement (a diamond arrangement).

The light-emitting diodes EDr1, EDg1a, EDb1, EDg1b, ..., EDb4, EDg4a, EDr4, EDg4b may be electrically connected to corresponding data lines through corresponding pixel circuits. The odd-numbered data lines DL1 and DL3 among the data lines may be electrically connected to red light-emitting diodes and blue light-emitting diodes, and the even-numbered data lines DL2 and DL4 among the data lines may be electrically connected to green light-emitting diodes.

The first red light-emitting diode EDr1 may be electrically connected to the [1,1]th pixel circuit PC11, the second red light-emitting diode EDrb may be electrically connected to the [1,2]th pixel circuit PC12, the third blue light-emitting diode EDb3 may be electrically connected to the [2,1]th pixel circuit PC21, and the fourth blue light-emitting diode EDb4 may be electrically connected to the [2,2]th pixel circuit PC22. The [1,1]th pixel circuit PC11, the [1,2]th pixel circuit PC12, the [2,1]th pixel circuit PC21, and the [2,2]th pixel circuit PC22 may each be electrically connected to the first data line DL1. The first red light-emitting diode EDr1 and the second red light-emitting diode EDr2 may emit red light. The third blue light-emitting diode EDb3 and the fourth blue light-emitting diode EDb4 may emit blue light.

The first blue light-emitting diode EDb1 may be electrically connected to the [1,5]th pixel circuit PC15, the second blue light-emitting diode EDb2 may be electrically connected to the [1,6]th pixel circuit PC16, the third red light-emitting diode EDr3 may be electrically connected to the [2,5]th pixel circuit PC25, and the fourth red light-emitting diode EDr4 may be electrically connected to the [2,6]th pixel circuit PC26. The [1,5]th pixel circuit PC15, the [1,6]th pixel circuit PC16, the [2,5]th pixel circuit PC25, and the [2,6]th pixel circuit PC26 may each be electrically connected to the third data line DL3. The first blue light-emitting diode EDb1 and the second blue light-emitting diode EDb2 may blue light. The third red light-emitting diode EDr3 and the fourth red light-emitting diode EDr4 may emit red light.

That is, one pair of pixel circuits PC11 and PC12 connected to the red light-emitting diodes EDr1 and EDr2 emitting red light and one pair of pixel circuits PC21 and PC22 connected to the blue light-emitting diodes EDb3 and EDb4 emitting blue light may be alternately arranged in the second direction (the direction y) for the first data line DL1. One pair of pixel circuits PC15 and PC16 connected to the blue light-emitting diodes EDb1 and EDb2 emitting blue light and one pair of pixel circuits PC25 and PC26 connected to the red light-emitting diodes EDr3 and EDr4 emitting red light may be alternately arranged in the second direction (the direction y) for the third data line DL3.

The 1st-1 green light-emitting diode EDg1a may be electrically connected to the [1,3]th pixel circuit PC13, the 2nd-1 green light-emitting diode EDg2a may be electrically connected to the [1,4]th pixel circuit PC14, the 3rd-1 green light-emitting diode EDg3a may be electrically connected to the [2,3]th pixel circuit PC23, and the 4th-1green light-emitting diode EDg4a may be electrically connected to the [2,4]th pixel circuit PC24. The [1,3]th pixel circuit PC13, the [1,4]th pixel circuit PC14, the [2,3]th pixel circuit PC23, and the [2,4]th pixel circuit PC24 may each be electrically connected to the second data line DL2. The 1st-1 green light-emitting diode EDg1a, the2nd-1 green light-emitting diode EDg2a, the 3rd-1green light-emitting diode EDg3a, and the4th-1 green light-emitting diode EDg4a may emit green light.

The 1st-2 green light-emitting diode EDg1b may be electrically connected to the [1,7]th pixel circuit PC17, the 2nd-2 green light-emitting diode EDg2b may be electrically connected to the [1,8]th pixel circuit PC18, the 3rd-2 green light-emitting diode EDg3b may be electrically connected to the [2,7]th pixel circuit PC27, and the 4th-2 green light-emitting diode EDg4b may be electrically connected to the [2,8]th pixel circuit PC28. The [1,7]th pixel circuit PC17, the [1,8]th pixel circuit PC18, the [2,7]th pixel circuit PC27, and the [2,8]th pixel circuit PC28 may each be electrically connected to the fourth data line DL4. The1st-2 green light-emitting diode EDg1b, the 2nd-2 green light-emitting diode EDg2b, the 3rd-2 green light-emitting diode EDg3b, and the 4th-2 green light-emitting diode EDg4b may emit green light.

Each of the second data line DL2 and the fourth data line DL4 may be electrically connected to green light-emitting diodes emitting green light. A data signal transmitted by each of the second data line DL2 and the fourth data line DL4 may include only data voltages for driving pixels that emit green light.

A first light-emitting diode column in which the red light-emitting diode EDr1 and the blue light-emitting diode EDb3 alternate with each other in the second direction (the direction y), a second light-emitting diode column in which the green light-emitting diodes EDg1a and EDg3a emitting green light are arranged, a third light-emitting diode column in which the blue light-emitting diode EDb1 and the red light-emitting diode EDr3 alternate with each other in the second direction (the direction y), and a fourth light-emitting diode column in which the green light-emitting diodes EDg1b and EDg3b are arranged may be sequentially repeated in the first direction (the direction x).

Referring to FIG. 14, the first first gate signal GWa[1] may be transmitted to the first first gate line GWLa1, the second first gate signal GWa[2] may be transmitted to the second first gate line GWLa2, the first second gate signal GWb[1] may be transmitted to the first second gate line GWLb1, and the second second gate signal GWb[2] may be transmitted to the second second gate line GWLb2. The gate signals GWa[1], GWa[2], GWb[1], and GWb[2] may be supplied as square wave signals in which an on voltage at which the connected second transistors T2 (refer to FIG. 4) may be turned on and an off voltage at which the connected second transistors T2 (refer to FIG. 4) may be turned off are repeatedly output.

The first gate driver 12 (refer to FIG. 2) may be configured to sequentially supply the first gate signals GWa[1] and GWa[2] to the first gate lines GWLa1 and GWLa2. The second first gate signal GWa[2] may be output phase-delayed by 1 horizontal period (1H) from the first first gate signal GWa[1].

The second gate driver 13 (refer to FIG. 2) may be configured to sequentially supply the second gate signals GWb[1] and GWb[2] to the second gate lines GWLb1 and GWLb2. The first second gate signal GWb[1] may be output phase-delayed by a certain period from the first first gate signal GWa[1]. For example, the first second gate signal GWb[1] may be output phase-delayed by 0.5 horizontal period (0.5H) from the first first gate signal GWa[1]. The second second gate signal GWb[2] may be output phase-delayed by 1 horizontal period (1H) from the first second gate signal GWb[1].

The data driver 15 (refer to FIG. 2) may be configured to supply the first data signal D[1] to the first data line DL1, supply the second data signal D[2] to the second data line DL2, supply the third data signal D[3] to the third data line DL3, and supply a fourth data signal D[4] to the fourth data line DL4.

The first data signal D[1] may include the red data voltage R11 corresponding to the [1,1]th pixel circuit PC11, the red data voltage R12 corresponding to the [1,2]th pixel circuit PC12, a blue data voltage B22 corresponding to the [2,2]th pixel circuit PC22, and a blue data voltage B21 corresponding to the [2,1]th pixel circuit PC21, which are sequentially output. The second data signal D[2] may include a green data voltage G13 corresponding to the [1,3]th pixel circuit PC13, a green data voltage G14 corresponding to the [1,4]th pixel circuit PC14, a green data voltage G24 corresponding to the [2,4]th pixel circuit PC24, and a green data voltage G23 corresponding to the [2,3]th pixel circuit PC23, which are sequentially output. The third data signal D[3] may include a blue data voltage B15 corresponding to the [1,5]th pixel circuit PC15, a blue data voltage B16 corresponding to the [1,6]th pixel circuit PC16, a red data voltage R26 corresponding to the [2,6]th pixel circuit PC26, and a red data voltage R25 corresponding to the [2,5]th pixel circuit PC25, which are sequentially output. The fourth data signal D[4] may include a green data voltage G17 corresponding to the [1,7]th pixel circuit PC17, a green data voltage G18 corresponding to the [1,8]th pixel circuit PC18, a green data voltage G28 corresponding to the [2,8]th pixel circuit PC28, and a green data voltage G27 corresponding to the [2,7]th pixel circuit PC27, which are sequentially output.

In other words, each of the data signals D[1], D[2], D[3], and D[4] may sequentially output a data voltage corresponding to the pixel circuits PC11, PC13, PC15, and PC17 connected to the first first gate line GWLa1, a data voltage corresponding to the pixel circuits PC12, PC14, PC16, and PC18 connected to the first second gate line GWLb1, a data voltage corresponding to the pixel circuits PC22, PC24, PC26, and PC28 connected to the second first gate line GWLa2, and a data voltage corresponding to the pixel circuits PC21, PC23, PC25, and PC27 connected to the second second gate line GWLb2.

The second data signal D[2] transmitted by the second data line DL2 and the fourth data signal D[4] transmitted by the fourth data line DL4 may include only data voltages for driving pixels that emit green light, and thus, power consumption for data voltage toggling may be reduced. In addition, when an image pattern including a boundary extending in a second direction (a direction y), such as the image pattern PTN shown in FIG. 9, is displayed, the number of times a data voltage changes may be reduced.

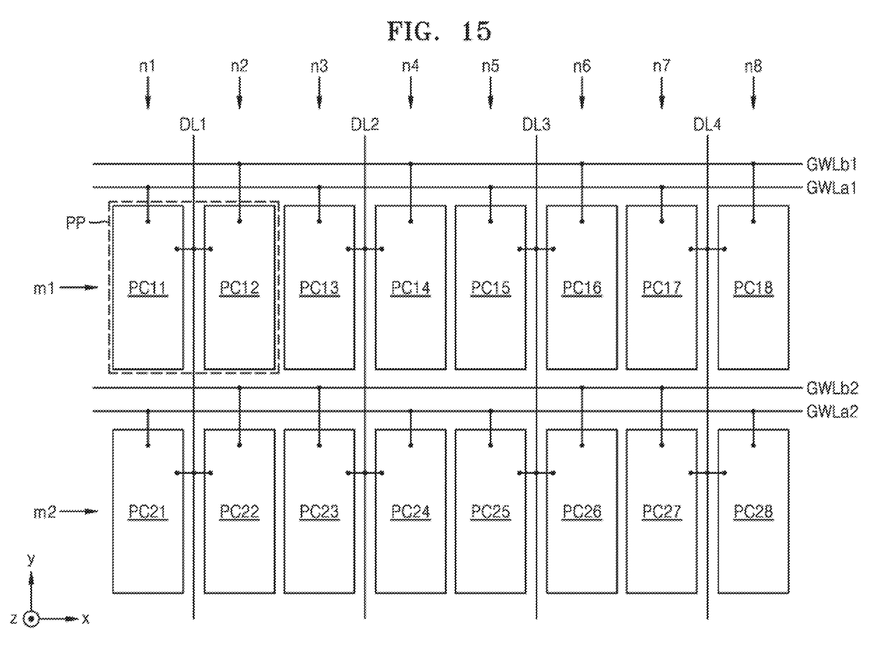

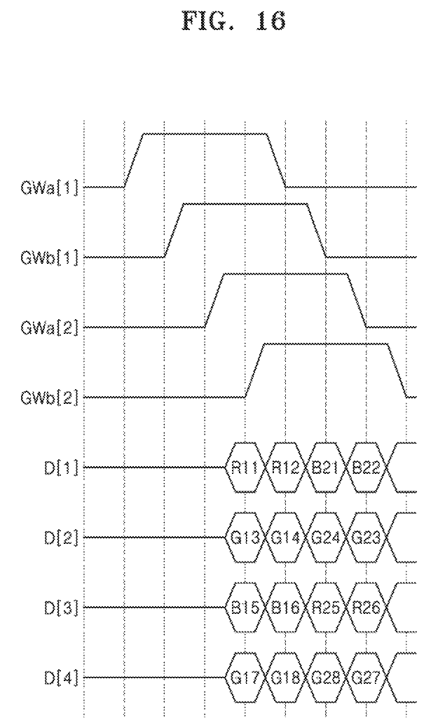

FIG. 15 is a diagram for schematically describing a connection between pixel circuits and data lines and gate lines, according to an embodiment. FIG. 16 is a diagram for describing gate voltages and data voltages that are applied to the pixel circuits shown in FIG. 15.

Referring to FIG. 15, pixel circuits PCmn may be arranged in a matrix in a first direction (a direction x) and a second direction (a direction y). In this regard, m indicates a pixel circuit row where a pixel circuit is positioned, and n indicates a pixel circuit column where the pixel circuit is positioned. In this regard, each of m and n is a natural number of 1 or greater. Although FIG. 15 shows an extract of sixteen pixel circuits PC11, PC12, ..., PC28 arranged in a 2×8 matrix, one or more embodiments are not limited thereto. The display apparatus 10 may include more pixel circuits PCmn and signal lines.

First gate lines may include the first first gate line GWLa1 and the second first gate line GWLa2 extending in the first direction (the direction x). Second gate lines may include the first second gate line GWLb1 and the second second gate line GWLb2 extending in the first direction (the direction x). Data lines may include the first data line DL1, the second data line DL2, the third data line DL3, and a fourth data line DL4 each extending in the second direction (the direction y). Each of the pixel circuits PCmn may be electrically connected to a corresponding one of the data lines and a corresponding one of the first gate lines and the second gate lines.

A pair of pixel circuit columns neighboring each other in the first direction (the direction x) may be electrically connected to one corresponding data line. For example, the pixel circuits PC11 and PC21 arranged in a first pixel circuit column n1 and the pixel circuits PC12 and PC22 arranged in a second pixel circuit column n2 may be electrically connected to the first data line DL1. The pixel circuits PC13 and PC23 arranged in a third pixel circuit column n3 and the pixel circuits PC14 and PC24 arranged in a fourth pixel circuit column n4 may be electrically connected to the second data line DL2. The pixel circuits PC15 and PC25 arranged in a fifth pixel circuit column n5 and the pixel circuits PC16 and PC26 arranged in a sixth pixel circuit column n6 may be electrically connected to the third data line DL3. The pixel circuits PC17 and PC27 arranged in a seventh pixel circuit column n7 and the pixel circuits PC18 and PC28 arranged in an eighth pixel circuit column n8 may be electrically connected to the fourth data line DL4.

One of the two pixel circuits constituting the pixel circuit pair PP may be electrically connected to a corresponding first gate line, and the other may be electrically connected to a corresponding second gate line. The pixel circuits PC11, PC13, PC15, and PC17 arranged in odd-numbered pixel circuit columns of an odd-numbered pixel circuit row m1 may be electrically connected to the first first gate line GWLa1, and the pixel circuits PC12, PC14, PC16, and PC18 arranged in even-numbered pixel circuit columns of the odd-numbered pixel circuit row m2 among the pixel circuits PCmn may be electrically connected to the first second gate line GWLb1. Among pixel circuits arranged in an even-numbered pixel circuit row m2, the pixel circuits PC21 and PC25 connected to the odd-numbered data lines DL1 and DL3 and arranged in odd-numbered columns and the pixel circuits PC24 and PC28 connected to the even-numbered data lines DL2 and DL4 and arranged in even-numbered columns may be electrically connected to the second first gate line GWLa2. Among the pixel circuits arranged in the even-numbered pixel circuit row m1, the pixel circuits PC22 and PC26 connected to the odd-numbered data lines DL1 and DL3 and arranged in even-numbered columns and the pixel circuits PC23 and PC27 connected to the even-numbered data lines DL2 and DL4 and arranged in odd-numbered columns may be electrically connected to the second second gate line GWLb2.

Each of the pixel circuits PCmn may be electrically connected to a light-emitting diode. The pixel circuits PCmn shown in FIG. 15 may be connected to corresponding light-emitting diodes in the same manner as the connection between the pixel circuits PCmn and the light-emitting diodes EDr1, EDg1a, EDb1, EDg1b, ..., EDb4, EDg4a, EDr4, EDg4b described with reference to FIG. 13.

Referring to FIG. 16, the first first gate signal GWa[1] may be transmitted to the first first gate line GWLa1, the second first gate signal GWa[2] may be transmitted to the second first gate line GWLa2, the first second gate signal GWb[1] may be transmitted to the first second gate line GWLb1, and the second second gate signal GWb[2] may be transmitted to the second second gate line GWLb2. The gate signals GWa[1], GWa[2], GWb[1], and GWb[2] may be supplied as square wave signals in which an on voltage at which the connected second transistors T2 (refer to FIG. 4) may be turned on and an off voltage at which the connected second transistors T2 (refer to FIG. 4) may be turned off are repeatedly output.

The first gate driver 12 (refer to FIG. 2) may be configured to sequentially supply the first gate signals GWa[1] and GWa[2] to the first gate lines GWLa1 and GWLa2. The second first gate signal GWa[2] may be output phase-delayed by 1 horizontal period (1H) from the first first gate signal GWa[1].

The second gate driver 13 (refer to FIG. 2) may be configured to sequentially supply the second gate signals GWb[1] and GWb[2] to the second gate lines GWLb1 and GWLb2. The first second gate signal GWb[1] may be output phase-delayed by a certain period from the first first gate signal GWa[1]. For example, the first second gate signal GWb[1] may be output phase-delayed by 0.5 horizontal period (0.5H) from the first first gate signal GWa[1]. The second second gate signal GWb[2] may be output phase-delayed by 1 horizontal period (1H) from the first second gate signal GWb[1].

The data driver 15 (refer to FIG. 2) may be configured to supply the first data signal D[1] to the first data line DL1, supply the second data signal D[2] to the second data line DL2, supply the third data signal D[3] to the third data line DL3, and supply the fourth data signal D[4] to the fourth data line DL4.

The first data signal D[1] may include the red data voltage R11 corresponding to the [1,1]th pixel circuit PC11, the red data voltage R12 corresponding to the [1,2]th pixel circuit PC12, the blue data voltage B21 corresponding to the [2,1]th pixel circuit PC21, and the blue data voltage B22 corresponding to the [2,2]th pixel circuit PC22, which are sequentially output. The second data signal D[2] may include the green data voltage G13 corresponding to the [1,3]th pixel circuit PC13, the green data voltage G14 corresponding to the [1,4]th pixel circuit PC14, the green data voltage G24 corresponding to the [2,4]th pixel circuit PC24, and the green data voltage G23 corresponding to the [2,3]th pixel circuit PC23, which are sequentially output. The third data signal D[3] may include the blue data voltage B15 corresponding to the [1,5]th pixel circuit PC15, the blue data voltage B16 corresponding to the [1,6]th pixel circuit PC16, the red data voltage R25 corresponding to the [2,5]th pixel circuit PC25, and the red data voltage R26 corresponding to the [2,6]th pixel circuit PC26, which are sequentially output. The fourth data signal D[4] may include the green data voltage G17 corresponding to the [1,7]th pixel circuit PC17, the green data voltage G18 corresponding to the [1,8]th pixel circuit PC18, the green data voltage G28 corresponding to the [2,8]th pixel circuit PC28, and the green data voltage G27 corresponding to the [2,7]th pixel circuit PC27, which are sequentially output.

In other words, each of the data signals D[1], D[2], D[3], and D[4] may sequentially output a data voltage corresponding to the pixel circuits PC11, PC13, PC15, and PC17 connected to the first first gate line GWLa1, a data voltage corresponding to the pixel circuits PC12, PC14, PC16, and PC18 connected to the first second gate line GWLb1, a data voltage corresponding to the pixel circuits PC21, PC24, PC25, and PC28 connected to the second first gate line GWLa2, and a data voltage corresponding to the pixel circuits PC22, PC23, PC26, and PC27 connected to the second second gate line GWLb2.

Each of the second data signal D[2] transmitted by the second data line DL2 and the fourth data signal D[4] transmitted by the fourth data line DL4 may include only data voltages for driving pixels that emit green light, and thus, power consumption for data voltage toggling may be reduced. In addition, when an image pattern including a boundary extending in a second direction (a direction y), such as the image pattern PTN shown in FIG. 9, is displayed, data voltages of pixels having the same luminance may be continuously output to reduce the number of times a data voltage changes.

The display apparatus 10 according to embodiments may be applicable to various electronic devices. An electronic device according to an embodiment may include the above display apparatus 10 and may further include a module or apparatus having another additional function in addition to the display apparatus 10.

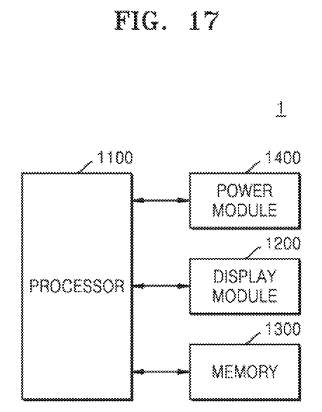

FIG. 17 is a block diagram of an electronic device 1 according to an embodiment.

Referring to FIG. 17, the electronic device 1 according to an embodiment may include a display module 1200, a processor 1100, a memory 1300, and a power module 1400.

The processor 1100 may include at least one of a CPU, an application processor (AP), a graphics processing unit (GPU), a communication processor (CP), an image signal processor (ISP), and the controller 20 (refer to FIG. 2). In an embodiment, the processor 1100 may be split into two or more from a functional or structural perspective. For example, the processor 1100 may include one or more processors and may include a main processor in the form of a first drive chip including a CPU, and an auxiliary processor in the form of a second drive chip including the controller 20 configured to receive an image signal (e.g., an image data signal IMG shown in FIG. 2) from the main processor and process the image signal to meet interface specifications of the display module 1200.

The memory 1300 may include at least one of a non-volatile memory and a volatile memory. Data information required for an operation of the processor 1100 or the display module 1200 may be stored in the memory 1300. When the processor 1100 executes an application stored in the memory 1300, an image data signal (e.g., an image data signal IMG shown in FIG. 2) and/or an input control signal (e.g., control signals CONT shown in FIG. 2) may be transmitted to the display module 1200, and the display module 1200 may process the received signal and output image information through a display screen.

The power module 1400 may include a power supply module, such as a power adapter or a battery device, and a power conversion module configured to convert power supplied by the power supply module to generate power required for an operation of the electronic device 1. Power conversion by the power conversion module may include, but is not limited to, DC-DC conversion, AC-DC conversion, and DC-AC conversion.

At least one of the above elements of the electronic device 1 may be included in a display apparatus according to the above embodiments. In some embodiments, some of the individual modules functionally included in one module may be included in the display apparatus, and the others may be provided separately from the display apparatus. For example, the display apparatus may include the display module 1200 and the auxiliary processor of the processor 1100, and the main processor of the processor 1100, the memory 1300, and the power module 1400 may be provided in the form of another apparatus within the electronic device 1 other than the display apparatus. As another example, the power module 1400 may be provided in the display apparatus and may supply power to the processor 1100 and the memory 1300 provided in the electronic device 1 other than the display apparatus, and one or more embodiments are not limited thereto.

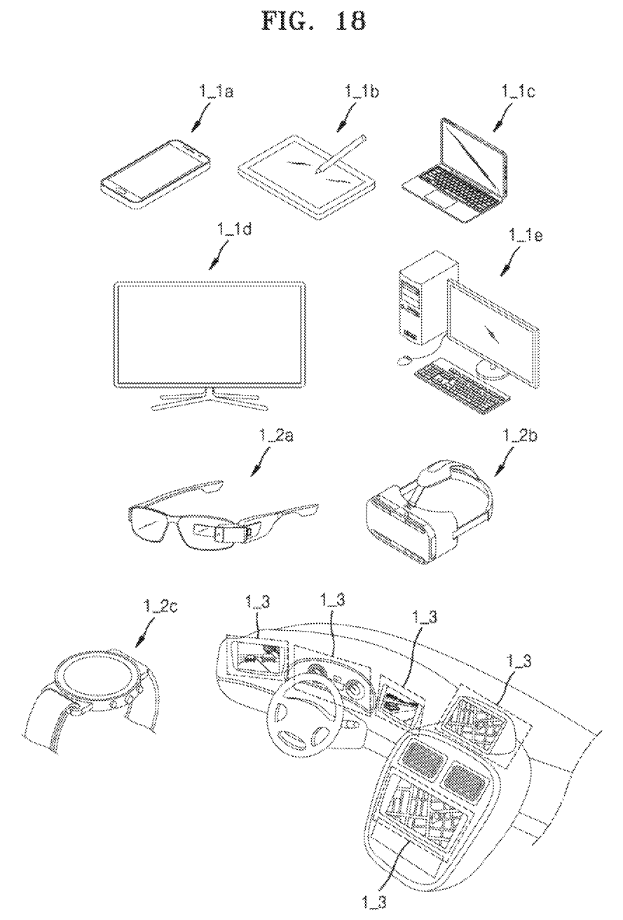

FIG. 18 schematically shows an electronic device according to various embodiments.

Referring to FIG. 18, various electronic devices to which a display apparatus according to embodiments is applied may include not only electronic devices for image display, such as a smartphone 1_1a, a tablet personal computer (PC) 1_1b, a laptop 1_1c, a TV 1_1d, and a desk monitor 1_1e, but also wearable electronic devices including a display module, such as smart glasses 1_2a, a head-mounted display 1_2b, and a smartwatch 1_2c, and automotive electronic devices 1_3 including a display module, such as a car's instrument cluster, a center information display (CID) arranged on a car's center fascia or dashboard, and a room mirror display.

The electronic device of FIG. 18 may include the elements shown in FIG. 17. For example, the smartphone 1_1a may include the display module 1200, the processor 1100, the memory 1300, and the power module 1400 shown in FIG. 17. The smartphone 1_1a may further include a communication module and a battery device. Power provided from the battery device may be converted through the power module 1400 and provided to the processor 1100, the memory 1300, and the display module 1200. In an embodiment, the display apparatus applied to the smartphone 1_1a may include the display module 1200 and may further include the power module 1400. The processor 1100 and the memory 1300 may be provided in the form of chips mounted on a motherboard, which is an external device, but are not limited thereto.

According to one or more of the above embodiments, a display apparatus with improved power consumption and an electronic device including the display apparatus may be implemented. However, one or more embodiments are not limited by such an effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the claims.

What is claimed is:

1. A display apparatus comprising:
pixel circuits arranged in a first direction and a second direction crossing the first direction;
first gate lines and second gate lines extending in the first direction; and
data lines extending in the second direction,
wherein, a pixel circuit arranged in an odd-numbered column and a pixel circuit arranged in an even-numbered column that neighbor each other in the first direction among the pixel circuits are electrically connected to one data line, and
pixel circuits arranged in odd-numbered columns of an odd-numbered row and pixel circuits arranged in even-numbered columns of an even-numbered row among the pixel circuits are each electrically connected to corresponding first gate lines among the first gate lines, and
pixel circuits arranged in even-numbered columns of the odd-numbered row and pixel circuits arranged in odd-numbered columns of the even-numbered row among the pixel circuits are each electrically connected to corresponding second gate lines among the second gate lines.

2. The display apparatus of claim 1, wherein each of the pixel circuits comprises:
a first transistor electrically connected between a driving voltage line and a light-emitting diode; and
a second transistor electrically connected between a corresponding data line among the data lines and the first transistor,
wherein the second transistor of one pixel circuit among the pixel circuit arranged in the odd-numbered column and the pixel circuit arranged in the even-numbered column that neighbor each other in the first direction is connected to a corresponding first gate line among the first gate lines, and the second transistor of another pixel circuit is connected to a corresponding second gate line among the second gate lines.

3. The display apparatus of claim 2, wherein the first transistor is an oxide semiconductor transistor.

4. The display apparatus of claim 2, wherein the second transistor comprises a second gate electrode, and
in a plan view, the second gate electrode has an island shape.

5. The display apparatus of claim 1, further comprising light-emitting diodes electrically connected to the pixel circuits,
wherein light-emitting diodes electrically connected to a same data line among the light-emitting diodes emit light of a same color.

6. The display apparatus of claim 5, wherein the light-emitting diodes comprise first light-emitting diodes emitting light of a first color, second light-emitting diodes emitting light of a second color, and third light-emitting diodes emitting light of a third color,
wherein, in each odd-numbered light-emitting diode column, the first light-emitting diodes and the second light-emitting diodes alternate with each other in the second direction, and in each even-numbered light-emitting diode column, the third light-emitting diodes are arranged in the second direction.

7. The display apparatus of claim 5, wherein the light-emitting diodes comprise first light-emitting diodes emitting light of a first color, second light-emitting diodes emitting light of a second color, and third light-emitting diodes emitting light of a third color,
wherein a first light-emitting diode column in which the first light-emitting diodes are arranged in the second direction, a second light-emitting diode column in which the second light-emitting diodes are arranged in the second direction, and a third light-emitting diode column in which the third light-emitting diodes are arranged in the second direction are sequentially repeated in the first direction.

8. The display apparatus of claim 1, further comprising light-emitting diodes electrically connected to the pixel circuits,
wherein the light-emitting diodes comprise first light-emitting diodes emitting light of a first color, second light-emitting diodes emitting light of a second color, and third light-emitting diodes emitting light of a third color,
wherein odd-numbered data lines among the data lines are electrically connected to the first light-emitting diodes and the third light-emitting diodes, and even-numbered data lines among the data lines are electrically connected to the second light-emitting diodes.

9. The display apparatus of claim 8, wherein a first light-emitting diode column in which the first light-emitting diodes and the third light-emitting diodes alternate with each other in the second direction, a second light-emitting diode column in which the second light-emitting diodes are arranged in the second direction, a third light-emitting diode column in which the third light-emitting diodes and the first light-emitting diodes alternate with each other in the second direction, and a fourth light-emitting diode column in which the second light-emitting diodes are arranged in the second direction are sequentially repeated in the first direction.

10. A display apparatus comprising:
a first pixel circuit and a second pixel circuit neighboring each other in a first pixel circuit row;
a third pixel circuit and a fourth pixel circuit neighboring each other in a second pixel circuit row;
a data driver configured to output data signals to data lines;
a first gate driver configured to sequentially output first gate signals to first gate lines; and
a second gate driver configured to sequentially output second gate signals to second gate lines,
wherein each of the first pixel circuit and the fourth pixel circuit is electrically connected to corresponding first gate lines among the first gate lines, and each of the second pixel circuit and the third pixel circuit is electrically connected to corresponding second gate lines among the second gate lines.

11. The display apparatus of claim 10, wherein the first pixel circuit, the second pixel circuit, the third pixel circuit, and the fourth pixel circuit are electrically connected to a first data line among the data lines.

12. The display apparatus of claim 11, wherein the first data line is arranged between the first pixel circuit and the second pixel circuit, and between the third pixel circuit and the fourth pixel circuit.

13. The display apparatus of claim 11, wherein a data signal corresponding to the first data line comprises a first data voltage corresponding to the first pixel circuit, a second data voltage corresponding to the second pixel circuit, a fourth data voltage corresponding to the fourth pixel circuit, and a third data voltage corresponding to the third pixel circuit,
wherein the first data voltage, the second data voltage, the fourth data voltage, and the third data voltage are sequentially output.

14. The display apparatus of claim 11, further comprising:
a first light-emitting diode electrically connected to the first pixel circuit;
a second light-emitting diode electrically connected to the second pixel circuit;
a third light-emitting diode electrically connected to the third pixel circuit; and
a fourth light-emitting diode electrically connected to the fourth pixel circuit,
wherein the first, second, third, and fourth light-emitting diodes emit light of a same color.

15. The display apparatus of claim 14, wherein a distance between the first pixel circuit and the first light-emitting diode is different from a distance between the second pixel circuit and the second light-emitting diode.

16. The display apparatus of claim 10, wherein each of the first, second, third, and fourth pixel circuits comprises:
a first transistor electrically connected between a driving voltage line and a light-emitting diode; and
a second transistor electrically connected between a corresponding data line among the data lines and the first transistor,
wherein the second transistor of each of the first pixel circuit and the fourth pixel circuit is electrically connected to the corresponding first gate lines among the first gate lines, and the second transistor of each of the second pixel circuit and the third pixel circuit is electrically connected to the corresponding second gate lines among the second gate lines.

17. An electronic device comprising:
a display apparatus;
a memory storing an image data signal or an input control signal; and
one or more processors configured to transfer the image data signal or the input control signal stored in the memory to the display apparatus,
wherein the display apparatus comprises:
a first pixel circuit and a second pixel circuit neighboring each other in a first pixel circuit row;
a third pixel circuit and a fourth pixel circuit neighboring each other in a second pixel circuit row;
first gate lines and second gate lines extending in a first direction; and
data lines extending in a second direction crossing the first direction,
wherein the first pixel circuit, the second pixel circuit, the third pixel circuit, and the fourth pixel circuit are electrically connected to a first data line among the data lines,
wherein each of the first pixel circuit and the fourth pixel circuit is electrically connected to corresponding first gate lines among the first gate lines, and each of the second pixel circuit and the third pixel circuit is electrically connected to corresponding second gate lines among the second gate lines.

18. The electronic device of claim 17, wherein each of the first, second, third, and fourth pixel circuits comprises:
a first transistor electrically connected between a driving voltage line and a light-emitting diode; and
a second transistor electrically connected between the first data line and the first transistor,
wherein the second transistor of each of the first pixel circuit and the fourth pixel circuit is electrically connected to the corresponding first gate lines among the first gate lines, and the second transistor of each of the second pixel circuit and the third pixel circuit is electrically connected to the corresponding second gate lines among the second gate lines.

19. The electronic device of claim 17, wherein the display apparatus further comprises:
a first light-emitting diode electrically connected to the first pixel circuit;
a second light-emitting diode electrically connected to the second pixel circuit;
a third light-emitting diode electrically connected to the third pixel circuit; and
a fourth light-emitting diode electrically connected to the fourth pixel circuit,
wherein the first, second, third, and fourth light-emitting diodes emit light of a same color.

20. The electronic device of claim 17, wherein the electronic device is for image display, a wearable electronic device, or an automotive electronic device.
